(19) United States
(12) Patent Application Publication
(10) Pub. No.: US 2024/0395723 A1
(43) Pub. Date: Nov. 28, 2024

(54) SEMICONDUCTOR DEVICE AND METHOD FOR MANUFACTURING SEMICONDUCTOR DEVICE

(71) Applicant: ROHM CO., LTD., Kyoto (JP)

(72) Inventor: Isamu NISHIMURA, Kyoto (JP)

(73) Assignee: ROHM CO., LTD., Kyoto (JP)

(21) Appl. No.: 18/797,548

(22) Filed: Aug. 8, 2024

Related U.S. Application Data
(63) Continuation of application No. PCT/JP2023/007081, filed on Feb. 27, 2023.

(30) Foreign Application Priority Data
Mar. 16, 2022 (JP) 2022-041713

(51) Int. Cl. H01L 23/538; H01L 21/48; H01L 23/00; H01L 23/31; H01L 23/36; H01L 23/498; H01L 25/065

(52) U.S. Cl. CPC H01L 23/5386; H01L 21/4846; H01L 23/49894; H01L 25/0655; H01L 23/3121; H01L 23/36; H01L 24/16; H01L 2224/16227

(57) ABSTRACT

A semiconductor device includes a substrate, a first semiconductor element, and a wiring. The substrate includes an obverse surface and a reverse surface facing away from each other in a first direction. The first semiconductor element includes a first electrode and a second electrode. The wiring includes a portion located between the substrate and each of the first electrode and the second electrode. The first electrode and the second electrode are electrically bonded to the wiring. The substrate is formed with a recess recessed from the obverse surface, and the wiring is accommodated in the recess. The wiring includes an exposed surface that is flush with the obverse surface. A roughness of the exposed surface is smaller than a roughness of the reverse surface.

### CROSS-REFERENCE TO RELATED APPLICATIONS

This application is a continuation application of International Application No. PCT/JP2023/007081, filed Feb. 27, 2023, which claims priority to Japanese Patent Application No. 2022-041713, filed Mar. 16, 2022. The contents of these applications are incorporated herein by reference in their entirety.

### TECHNICAL FIELD

The present disclosure relates to a semiconductor device and a method for manufacturing the same.

### BACKGROUND ART

JP-A-2020-188085 discloses an example of a semiconductor device provided with a semiconductor element having a lateral structure (HEMT). The semiconductor element has a first electrode and a second electrode. In the semiconductor device, the semiconductor element is bonded to a die pad. The first electrode and the second electrode are electrically connected via wires to a plurality of terminal leads located around the die pad.

In the semiconductor device disclosed in JP-A-2020-188085, transmission of a high-frequency electric signal may be required to achieve more efficient power conversion. The current corresponding to a high-frequency electric signal flows concentratively near the surface of a conductor. Accordingly, if the surfaces of the wires and the terminal leads are relatively rough, the flow of the current near the surfaces will be inhibited. This causes an increase of a transmission loss in high-frequency transmission.

### BRIEF DESCRIPTION OF THE DRAWINGS

FIG. 1 is a plan view showing a semiconductor device according to a first embodiment of the present disclosure.

FIG. 2 is a plan view corresponding to FIG. 1, from which a sealing resin is omitted.

FIG. 3 is a plan view corresponding to FIG. 2, as seen through a plurality of first semiconductor elements, a plurality of second semiconductor elements, a drive element, and a control element.

FIG. 4 is a bottom view showing the semiconductor device in FIG. 1.

FIG. 5 is a cross-sectional view along line V-V in FIG. 2.

FIG. 6 is a cross-sectional view along line VI-VI in FIG. 2.

FIG. 7 is a cross-sectional view along line VII-VII in FIG. 2.

FIG. 8 is a cross-sectional view along line VIII-VIII in FIG. 2.

FIG. 9 is a partially enlarged view of FIG. 2.

FIG. 10 is a partially enlarged view of FIG. 5, and shows an obverse surface of a substrate and a wiring.

FIG. 11 is a partially enlarged view of FIG. 5, and shows a reverse surface of the substrate.

FIG. 12 is a cross-sectional view for describing a manufacturing step of the semiconductor device in FIG. 1.

FIG. 13 is a cross-sectional view for describing a manufacturing step of the semiconductor device in FIG. 1.

FIG. 14 is a cross-sectional view for describing a manufacturing step of the semiconductor device in FIG. 1.

FIG. 15 is a cross-sectional view for describing a manufacturing step of the semiconductor device in FIG. 1.

FIG. 16 is a cross-sectional view for describing a manufacturing step of the semiconductor device in FIG. 1.

FIG. 17 is a cross-sectional view for describing a manufacturing step of the semiconductor device in FIG. 1.

FIG. 18 is a cross-sectional view for describing a manufacturing step of the semiconductor device in FIG. 1.

FIG. 19 is a cross-sectional view for describing a manufacturing step of the semiconductor device in FIG. 1.

FIG. 20 is a cross-sectional view for describing a manufacturing step of the semiconductor device in FIG. 1.

FIG. 21 is a cross-sectional view for describing a manufacturing step of the semiconductor device in FIG. 1.

FIG. 22 is a plan view showing a semiconductor device according to a variation of the first embodiment of the present disclosure, from which the sealing resin is omitted.

FIG. 23 is a plan view showing a semiconductor device according to a second embodiment of the present disclosure, from which a sealing resin is omitted.

FIG. 24 is a cross-sectional view along line XXIV-XXIV in FIG. 23.

FIG. 25 is a cross-sectional view along line XXV-XXV in FIG. 23.

FIG. 26 is a bottom view showing a semiconductor device according to a third embodiment of the present disclosure.

FIG. 27 is a cross-sectional view showing the semiconductor device in FIG. 26.

FIG. 28 is a plan view showing a semiconductor device according to a fourth embodiment of the present disclosure.

FIG. 29 is a cross-sectional view along line XXIX-XXIX in FIG. 28.

FIG. 30 is a cross-sectional view along line XXX-XXX in FIG. 28.

FIG. 31 is a plan view showing a semiconductor device according to a fifth embodiment of the present disclosure.

FIG. 32 is a cross-sectional view along line XXXII-XXXII in FIG. 31.

FIG. 33 is a cross-sectional view along line XXXIII-XXXIII in FIG. 31.

### DETAILED DESCRIPTION OF EMBODIMENTS

Preferred embodiments of the present disclosure will be described with reference to the accompanying drawings.

### First Embodiment

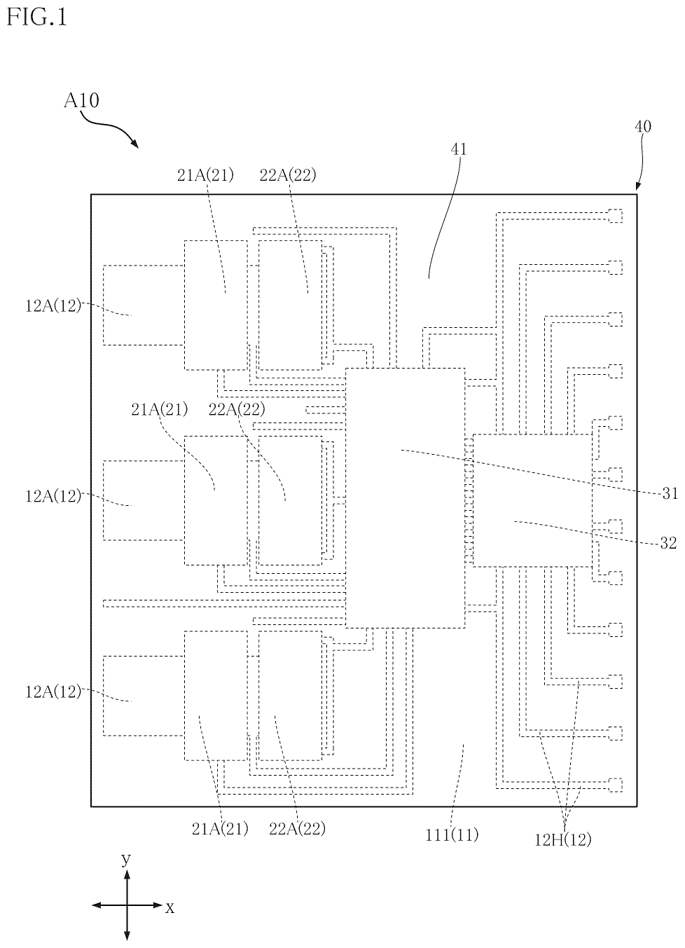

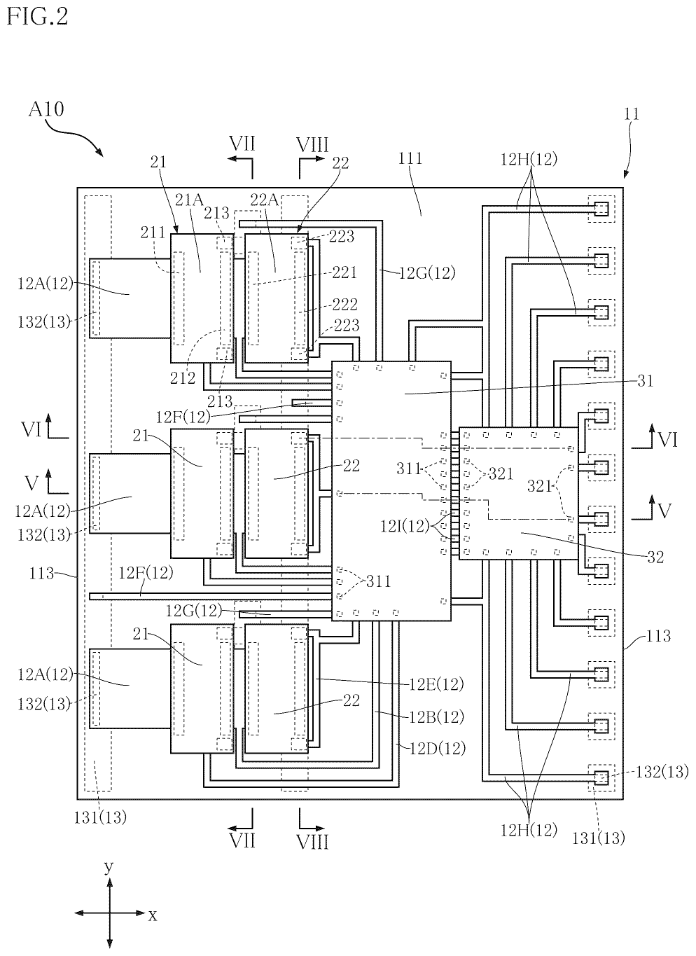

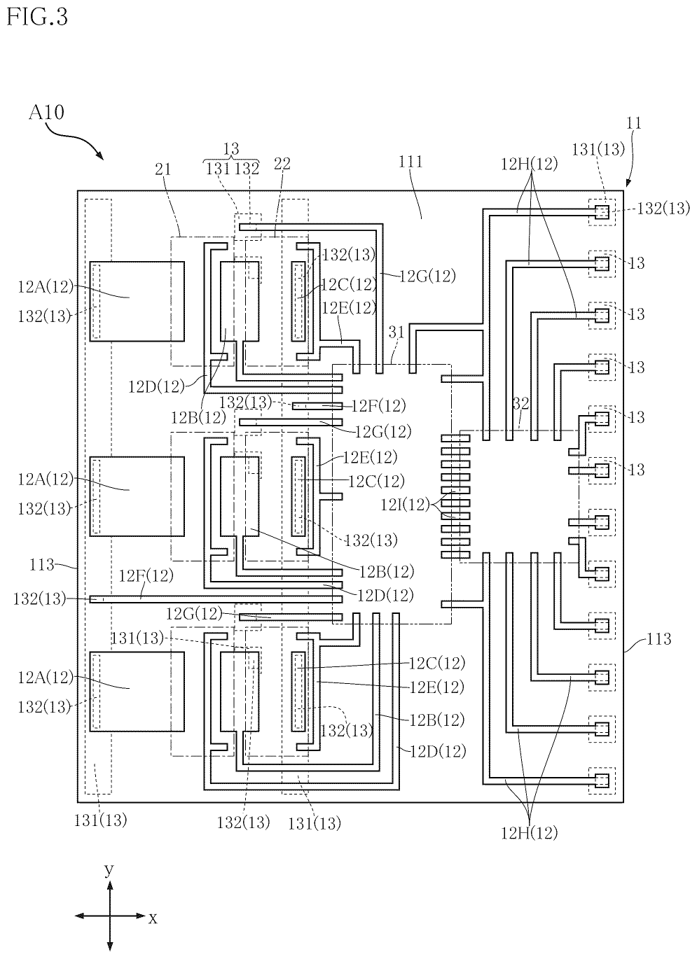

With reference to FIGS. 1 to 11, a semiconductor device A10 according to a first embodiment of the present disclosure will be described. The semiconductor device A10 includes a substrate 11, a plurality of wirings 12, a plurality of connecting wirings 13, a plurality of first semiconductor elements 21, a plurality of second semiconductor elements 22, a bonding layer 29, a drive element 31, a control element 32, a sealing resin 40, and a plurality of terminals 50. The semiconductor device A10 is provided in a resin package for surface-mounting on a wiring board. For convenience of omits the sealing resin 40. For understanding, FIG. 2 convenience of understanding, FIG. 3 corresponding to FIG. 2 shows the first semiconductor elements 21, the second semiconductor elements 22, the drive element 31, and the control element 32 as transparent. In FIG. 3, the first semiconductor elements 21, the second semiconductor elements 22, the drive element 31, and the control element 32 are indicated by imaginary lines (two-dot chain lines).

In the description of the semiconductor device A10, the normal direction of a first obverse surface 111 of the substrate 11, which will be described below, is referred to as a “first direction z” for convenience. A direction perpendicular to the first direction z is referred to as a “second direction x”. The direction perpendicular to the first direction z and the second direction x is referred to as a “third direction y”. As shown in FIG. 1, the semiconductor device A10 has a rectangular shape as viewed in the first direction z.

The semiconductor device A10 converts the DC power supplied from the outside to the semiconductor device A10 into three-phase AC power by means of the first semiconductor elements 21 and the second semiconductor elements 22. The semiconductor device A10 may be used for the drive control of a brushless DC motor.

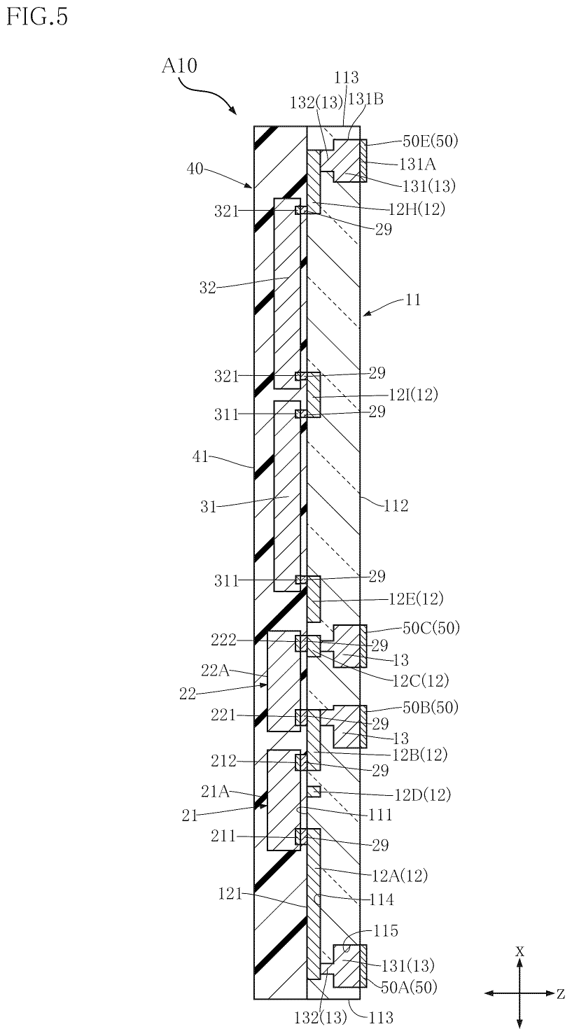

As shown in FIGS. 5 to 8, the substrate 11 has the wirings 12 arranged thereon, and accommodates at least a portion of each connecting wiring 13. The substrate 11 is electrically insulative. The substrate 11 is made of a material containing glass. The glass may be any one of soda-lime glass, borosilicate glass, and quartz glass. Thus, the composition of the substrate 11 includes silicon dioxide (SiO₂).

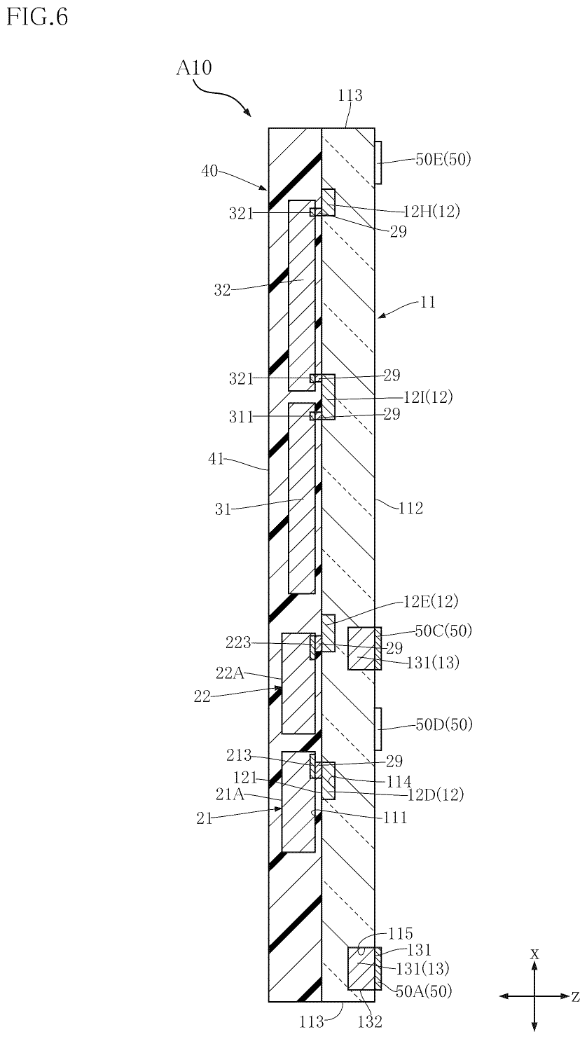

As shown in FIGS. 5 and 6, the substrate 11 has an obverse surface 111, a reverse surface 112, two side surfaces 113, a plurality of recesses 114, and a plurality of through-holes 115. The obverse surface 111 and the reverse surface 112 face away from each other in the first direction z. The obverse surface 111 faces the sealing resin 40. The reverse surface 112 is exposed to the outside. In another example, the semiconductor device A10 may include an insulator covering the reverse surface 112. The insulator is made of a material containing a black epoxy resin, for example. When the semiconductor device A10 is mounted on a wiring board, the reverse surface 112 faces the wiring board.

As shown in FIGS. 2 to 6, the two side surfaces 113 face away from each other in the second direction x. The two side surfaces 113 are spaced apart from each other in the second direction x.

As shown in FIGS. 5 to 10, the recesses 114 are recessed from the substrate 11. As shown in FIGS. 5 to 8, the through-holes 115 are located between the reverse surface 112 and the recesses 114 in the first direction z. The through-holes 115 are connected to the reverse surface 112. Each of the through-holes 115 is connected to one of the recesses 114. The dimension of each through-hole 115 in the first direction z is larger than that of each recess 114 in the first direction z.

As shown in FIGS. 2, 5, and 6, the first semiconductor elements 21 face the obverse surface 111 of the substrate 11. The first semiconductor elements 21 are aligned in the third direction y. The first semiconductor elements 21 are transistors (switching elements) mainly used for power conversion. Each of the first semiconductor elements 21 is made of a material containing a nitride semiconductor. In the semiconductor device A10, each of the first semiconductor elements 21 is a high electron mobility transistor (HEMT) made of a material containing gallium nitride (GaN).

As shown in FIGS. 2, 5, and 6, each of the first semiconductor elements 21 has a first upper surface 21A, a first electrode 211, a second electrode 212, and two first gate electrodes 213. The first upper surface 21A faces the same side as the obverse surface 111 of the substrate 11 in the first direction z. The first electrode 211, the second electrode 212, and the two first gate electrodes 213 are located on the opposite side from the first upper surface 21A in the first direction z. Thus, the first electrode 211, the second electrode 212, and the two first gate electrodes 213 face the substrate 11.

As shown in FIG. 2, the first electrode 211 and the second electrode 212 extend in the third direction y. The first electrode 211 and the second electrode 212 are spaced apart from each other in the second direction x. The first electrode 211 passes the current corresponding to the power before conversion by the first semiconductor element 21. Thus, the first electrode 211 corresponds to the drain of the semiconductor element 21. The second electrode 22 passes the current corresponding to the power after conversion by the first semiconductor element 21. Thus, the second electrode 212 corresponds to the source of the semiconductor element 21.

As shown in FIG. 2, the two first gate electrodes 213 are located on the respective sides of the second electrode 212 in the third direction y. At least one of the two first gate electrodes 213 receives a gate voltage applied for driving the first semiconductor element 21. As viewed in the first direction z, each of the two first gate electrodes 213 is smaller in area than each of the first electrode 211 and the second electrode 212. The shapes and arrangements of the first electrode 211, the second electrode 212, and the two first gate electrodes 213 in each first semiconductor element 21 are cited by way of example.

As shown in FIGS. 2, 7, and 8, the second semiconductor elements 22 face the obverse surface 111 of the substrate 11. The second semiconductor elements 22 are spaced apart from the first semiconductor elements 21 in the second direction X. The second semiconductor elements 22 are aligned in the third direction y. Each of the second semiconductor elements 22 has the same structure and the same function as each of the first semiconductor elements 21. Thus, in the description of the second semiconductor elements 22, a description overlapping with that of the first semiconductor elements 21 will be omitted.

As shown in FIGS. 2, 7, and 8, each of the second semiconductor elements 22 has a second upper surface 22A, a third electrode 221, a fourth electrode 222, and two second gate electrodes 223. The second upper surface 22A faces the same side as the obverse surface 111 of the substrate 11 in the first direction z. The third electrode 221, the fourth electrode 222, and the two second gate electrodes 223 are located on the opposite side from the second upper surface 22A in the first direction z. Thus, the third electrode 221, the fourth electrode 222, and the two second gate electrodes 223 face the substrate 11.

The structure and function of the third electrode 221 correspond to those of the first electrode 211 of each first semiconductor element 21. The structure and function of the fourth electrode 222 correspond to those of the second electrode 212 of each first semiconductor element 21. The structure and function of each of the two second gate electrodes 223 correspond to those of each of the two first gate electrodes 213 of each first semiconductor element 21. As with the case of the first semiconductor elements 21, the shapes and arrangements of the third electrode 221, the fourth electrode 222, and the two second gate electrodes 223 of each second semiconductor element 22 are cited by way of example.

As shown in FIGS. 2, 5, and 6, the drive element 31 faces the obverse surface 111 of the substrate 11. The drive element 31 is located on the opposite side from the first semiconductor elements 21 with respect to the second semiconductor elements 22 in the second direction x. The drive element 31 is electrically connected to the first semiconductor elements 21 and the second semiconductor elements 22. The drive element 31 is a gate driver that applies gate voltages to the two first gate electrodes 213 of each first semiconductor element 21 and the two second gate electrodes 223 of each second semiconductor element 22. The drive element 31 has a plurality of electrodes 311. The electrodes 311 face the substrate 11.

As shown in FIGS. 2, 5, and 6, the control element 32 faces the obverse surface 111 of the substrate 11. The control element 32 is located on the opposite side from the first semiconductor elements 21 with respect to the second semiconductor elements 22 in the second direction x. Further, the control element 32 is located on the opposite side from the second semiconductor elements 22 with respect to the drive element 31 in the second direction x. The control element 32 is electrically connected to the drive element 31. The control element 32 controls the drive element 31. The control element 32 has a plurality of electrodes 321. The electrodes 321 face the substrate 11.

As shown in FIG. 3 and FIGS. 5 to 8, the wirings 12 are accommodated in the respective recesses 114 of the substrate 11. The wirings 12 are in contact with the substrate 11. The composition of the wirings 12 includes copper (Cu), for example. The wirings 12, together with the connecting wirings 13 and the terminals 50, form conductive paths that connect the first semiconductor elements 21, the second semiconductor elements 22, the drive element 31, and the control element 32 to the wiring board on which the semiconductor device A10 is mounted.

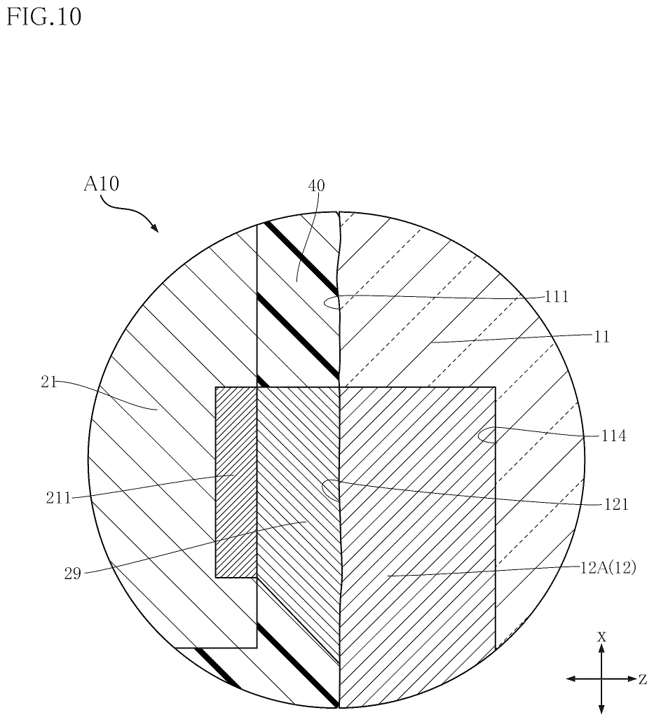

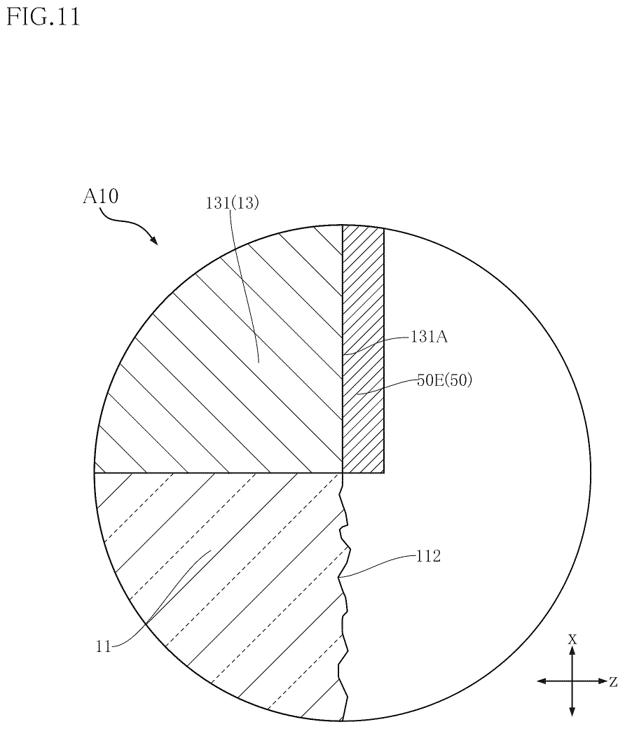

As shown in FIGS. 5 to 9, each of the wirings 12 has an exposed surface 121 that is flush with the obverse surface 111 of the substrate 11. Thus, the wirings 12 do not protrude from the obverse surface 111. As shown in FIGS. 10 and 11, the roughness of the exposed surface 121 of each wiring 12 is smaller than the roughness of the reverse surface 112 of the substrate 11. Further, the roughness of the obverse surface 111 is smaller than the roughness of the reverse surface 112.

As shown in FIG. 3, the wirings 12 are surrounded by the periphery of the obverse surface 111 of the substrate 11 as viewed in the first direction z. The wirings 12 include a plurality of first wirings 12A, a plurality of second wirings 12B, a plurality of third wirings 12C, a plurality of first gate wirings 12D, a plurality of second gate wirings 12E, two detection wirings 12F, a plurality of boot wirings 12G, a plurality of control wirings 12H, and a plurality of relay wirings 12I.

As shown in FIG. 3, the first wirings 12A are aligned in the third direction y. As shown in FIG. 5, the first electrode 211 of each first semiconductor element 21 is electrically bonded to one of the first wirings 12A via the bonding layer 29. The bonding layer 29 is solder, for example. In another example, the bonding layer 29 may be a columnar metal formed in Cu—Cu bonding.

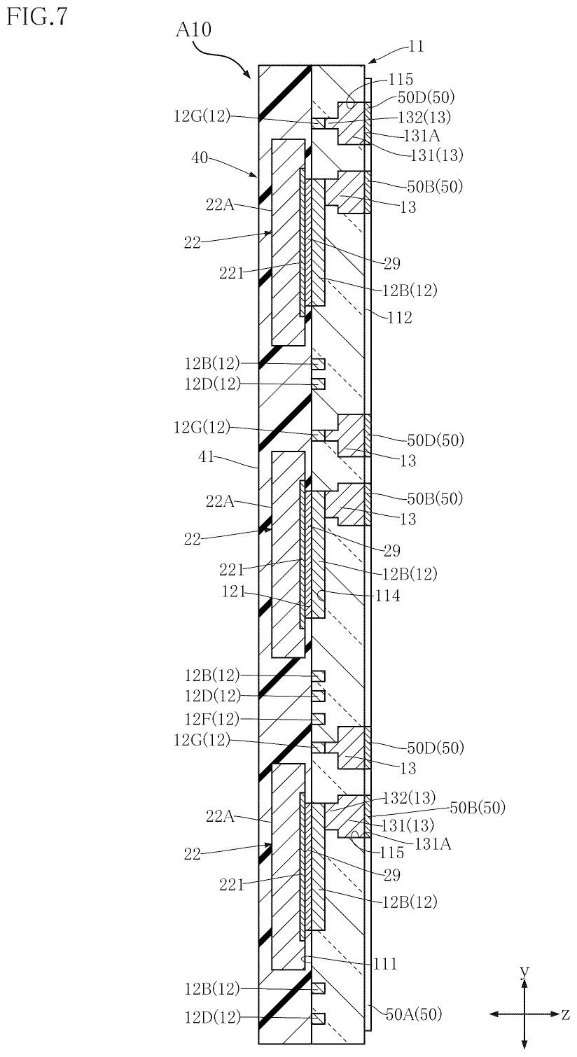

As shown in FIG. 3, the second wirings 12B are located on the opposite side from the first wirings 12A with the first gate wirings 12D therebetween in the second direction x. The second wirings 12B are aligned in the third direction y. As shown in FIG. 5, the second electrode 212 of each first semiconductor element 21 is electrically bonded to one of the second wirings 12B via the bonding layer 29. Further, as shown in FIG. 7, the third electrode 221 of each second semiconductor element 22 is electrically connected to one of the second wirings 12B via the bonding layer 29. Thus, the third electrodes 221 of the second semiconductor elements 22 are electrically connected to the second electrodes 212 of the first semiconductor elements 21 via the second wirings 12B.

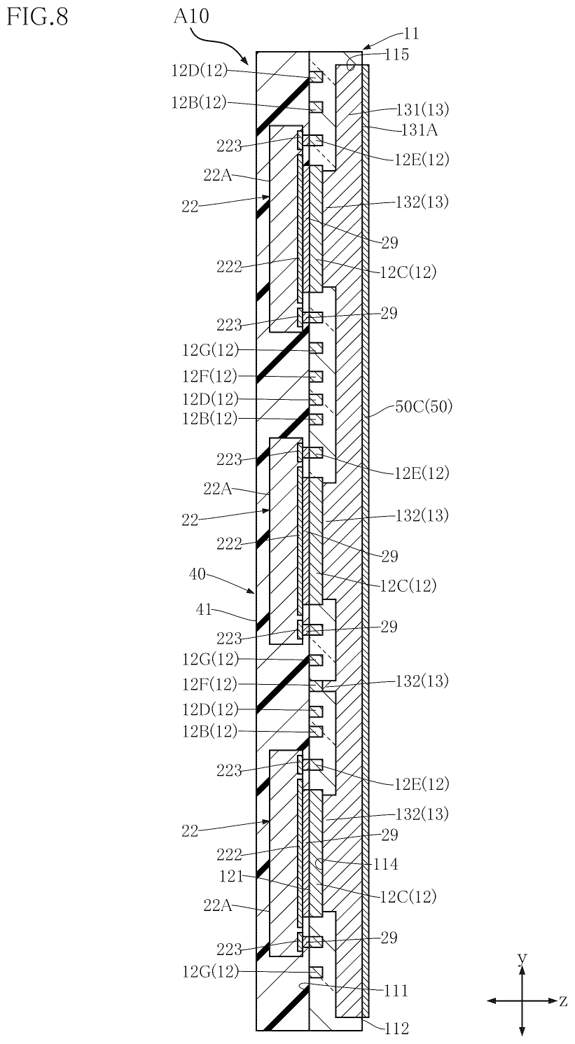

As shown in FIG. 3, the third wirings 12C are located on the opposite side from the first gate wirings 12D with respect to the second wirings 12B in the second direction x. The third wirings 12C are located adjacent to the second wirings 12B in the second direction x. The third wirings 12C are aligned in the third direction y. As shown in FIG. 8, the fourth electrode 222 of each second semiconductor element 22 is electrically bonded to one of the third wirings 12C.

As shown in FIG. 6, the two first gate electrodes 213 of each first semiconductor element 21 are electrically bonded to one of the first gate wirings 12D via the bonding layer 29. As shown in FIG. 8, the two second gate electrodes 223 of each second semiconductor element 22 are electrically bonded to one of the second gate wirings 12E via the bonding layer 29. Further, each of the first gate wirings 12D and the second gate wirings 12E is electrically bonded to one of the electrodes 311 of the drive element 31 via the bonding layer 29.

Each of the two detection wirings 12F and the boot wirings 12G is electrically bonded to one of the electrodes 311 of the drive element 31 via the bonding layer 29.

As shown in FIG. 5, each of the control wirings 12H is electrically bonded to one of the electrodes 321 of the control element 32 via the bonding layer 29. Further, some of the control wirings 12H are electrically bonded to some of the electrodes 311 of the drive element 31, respectively.

As shown in FIG. 3, each of the relay wirings 12I includes a portion located between the drive element 31 and the control element 32 in the second direction x. The relay wirings 12I are aligned in the third direction y. Each of the relay wirings 121 is electrically bonded to one of the electrodes 311 of the drive element 31 via the bonding layer 29, and to one of the electrodes 321 of the control element 32 via the bonding layer 29. This electrically connects the control element 32 to the drive element 31.

As shown in FIGS. 5 to 8, at least a portion of each connecting wiring 13 is accommodated in the substrate 11. The connecting wirings 13 are in contact with the substrate 11. The connecting wirings 13 electrically connect the first wirings 12A, the second wirings 12B, the third wirings 12C, the two detection wirings 12F, the boot wirings 12G, and the control wirings 12H and the terminals 50 to each other. Thus, each of the connecting wirings 13 is connected to a corresponding one of the wirings 12. The connecting wirings 13 are exposed from the reverse surface 112 of the substrate 11. As shown in FIG. 3, the connecting wirings 13 are surrounded by the periphery of the obverse surface 111 of the substrate 11 as viewed in the first direction z. The composition of the connecting wirings 13 includes copper (Cu), for example.

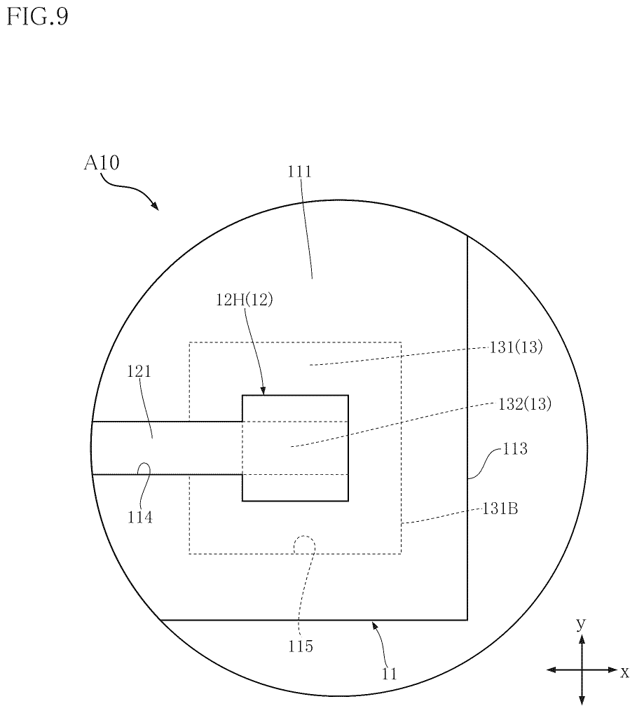

As shown in FIGS. 3 to 8, each of the connecting wirings 13 has a first portion 131 and at least one second portion 132. The second portion 132 is located between the first portion 131 and one of the wirings 12 in the first direction z. The first portion 131 is exposed from the reverse surface 112 of the substrate 11. The second portion 132 is connected to the wiring 12. As shown in FIG. 9, the area of a first portion 131 is larger than that of a second portion 132 as viewed in the first direction z.

As shown in FIGS. 5 to 8, the first portion 131 of each connecting wiring 13 has a first end surface 131A exposed from the reverse surface 112 of the substrate 11. Further, of the first portions 131 of the connecting wirings 13, the first portion 131 of the connecting wiring 13 electrically connected to the first wirings 12A and the first portion 131 of each of the connecting wirings 13 electrically connected to the respective control wirings 12H each have a second end surface 131B facing in the second direction x. Each of the second end surfaces 131B faces the same side as the side surface 113 closer to the second end surface 131B out of the two side surfaces 113 of the substrate 11.

As shown in FIG. 1 and FIGS. 5 to 8, the sealing resin 40 covers the wirings 12, the first semiconductor elements 21, the second semiconductor elements 22, the drive element 31, and the control element 32. The sealing resin 40 is electrically insulative. The sealing resin 40 is made of a material containing a black epoxy resin, for example. As shown in FIG. 1 and FIGS. 5 to 8, the sealing resin 40 has a top surface 41. The top surface 41 faces the same side as the obverse surface 111 of the substrate 11 in the first direction z.

As viewed in the first direction z, the sealing resin 40 overlaps with the obverse surface 111 of the substrate 11 and the exposed surface 121 of each wiring 12. As shown in FIGS. 5 to 8, the sealing resin 40 of the semiconductor device A10 is in contact with the obverse surface 111 and the exposed surface 121 of each wiring 12.

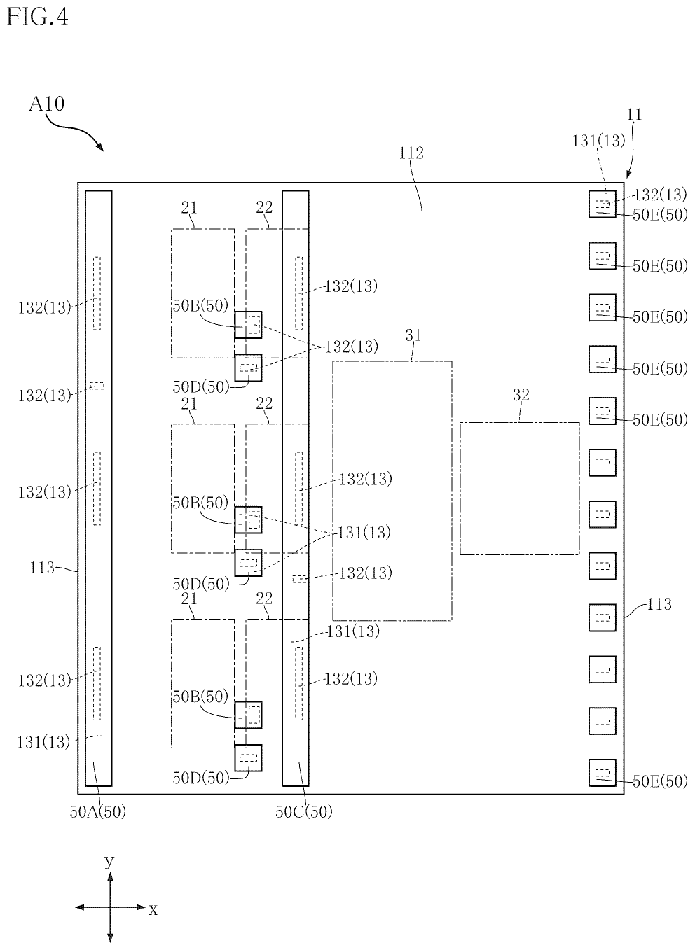

As shown in FIG. 4, the terminals 50 cover the respective connecting wirings 13, and are exposed to the outside. As shown in FIGS. 5 to 8, the terminals 50 cover the first end surfaces 131A of the respective connecting wirings 13 that are exposed from the reverse surface 112 of the substrate 11. The semiconductor device A10 is mounted onto a wiring board by soldering the terminals 50 to the wiring board. Each of the terminals 50 includes a plurality of metal layers. The metal layers include a nickel layer and a gold (Au) layer formed on a connecting wiring 13 in the stated order. In another example, the metal layers may include a nickel layer, a palladium (Pd) layer, and a gold layer: formed on a connecting wiring 13 in the stated order.

As shown in FIG. 4, the terminals 50 include a first terminal 50A, a plurality of second terminals 50B, a third terminal 50C, a plurality of boot terminals 50D, and a plurality of control terminals 50E.

The first terminal 50A is electrically connected to the first wirings 12A and one of the two detection wirings 12F. The third terminal 50C is electrically connected to the third wirings 12C and the other one of the two detection wirings 12F. The first terminal 50A and the third terminal 50C receive DC power that is to be converted by the first semiconductor elements 21 and the second semiconductor elements 22. The first terminal 50A is a positive electrode (P terminal). The third terminal 50C is a negative electrode (N terminal).

The second terminals 50B are electrically connected to the respective second wirings 12B. Each of the second terminals 50B is also electrically connected to one of a plurality of capacitors located outside the semiconductor device A10. The capacitors are elements of a boot strap circuit for the semiconductor device A10. The second terminals 50B output the U-phase, V-phase, and W-phase of a three-phase AC power converted by the first semiconductor elements 21 and the second semiconductor elements 22. The three-phase AC power is used to control the drive of a motor outside the semiconductor device A10.

The boot terminals 50D are electrically connected to the respective boot wirings 12G. Each of the boot terminals 50D is also electrically connected to one of a plurality of capacitors located outside the semiconductor device A10. When the drive element 31 applies gate voltage to the two first gate electrodes 213 of one of the first semiconductor elements 21, a current flows through the drive element 31 via the boot terminal 50D electrically connected to one of the capacitors and the corresponding the boot wiring 12G.

The control terminals 50E are electrically connected to the respective control wirings 12H. Thus, each of the control terminals 50E is electrically connected to at least one of the drive element 31 and the control element 32. One of the control terminals 50E receives the power for driving the drive element 31 and the control element 32. One of the control terminals 50E receives an electric signal for the control element 32. One of the control terminals 50E outputs an electric signal sent from the control element 32.

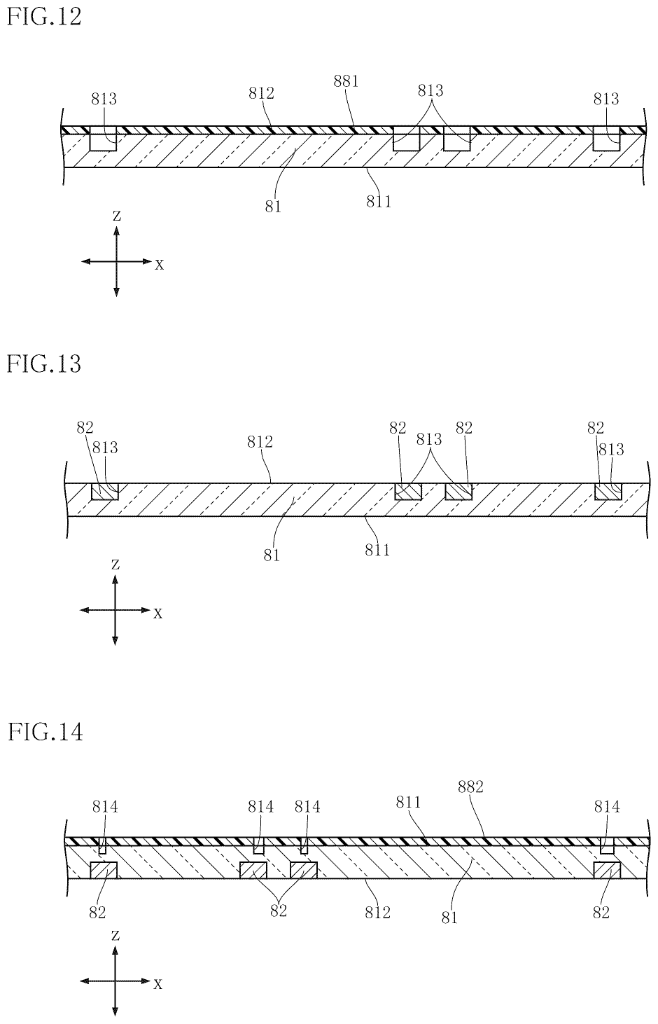

The following describes an example of a method for manufacturing the semiconductor device A10, with reference to FIGS. 12 to 21. The cross-sections shown in FIGS. 12 to 21 are taken along the same line as the cross-section shown in FIG. 5.

First, as shown in FIG. 12, a plurality of first recesses 813 are formed in a base member 81. The base member 81 comprises a plurality of substrates 11, including the substrate 11 of the semiconductor device A10, that are connected to each other in a direction perpendicular to the first direction z. The base member 81 has an obverse surface 811 and a reverse surface 812 facing away from each other in the first direction z. The base member 81 is made of a material containing glass. In the formation of the first recesses 813, a first mask layer 881 is formed first on the reverse surface 812 by lithographic patterning. Next, the first recesses 813 recessed from the reverse surface 812 are formed by reactive ion etching (RIE). Finally, the first mask layer 881 is removed. This completes the formation of the first recesses 813.

Nest, as shown in FIG. 13, a plurality of first metal layers 82 are formed to be accommodated in the respective first recesses 813. The first metal layers 82 will be formed into the first portions 131 of the connecting wirings 13 in the semiconductor device A10. In the formation of the first metal layers 82, an underlying layer is formed first to cover the reverse surface 812 of the base member 81 and the surface of the base member 81 defining the first recesses 813. The underlying layer includes a thin metal film made of titanium and in contact with the base member 81, and a thin metal film made of copper and formed on the thin film of titanium. The underlying layer is formed by sputtering. Next, lithographic patterning is performed on the underlying layer. Then, a plurality of copper plating layers are formed to be accommodated in the respective first recesses 813 by electrolytic plating with the underlying layer used as a conductive path. Next, a mask layer for lithographic patterning is removed. Finally, the underlying layer covering the reverse surface 812 is removed by wet etching using a mixed solution containing sulfuric acid (H₂SO₄) and hydrogen peroxide (H₂O₂). This completes the formation of the first metal layers 82.

Next, as shown in FIG. 14, a plurality of second recesses 814 are formed in the base member 81. In the formation of the second recesses 814, a second mask layer 882 is formed first on the obverse surface 811 by lithographic patterning. Next, the second recesses 814 are formed to be recessed from the obverse surface 811 by reactive ion etching. Finally, the second mask layer 882 is removed. This completes the formation of the second recesses 814. As viewed in the first direction z, one of the second recesses 814 overlaps with one of the first recesses 813. However, in this step, each of the second recesses 814 should not connect to any of the first recesses 813.

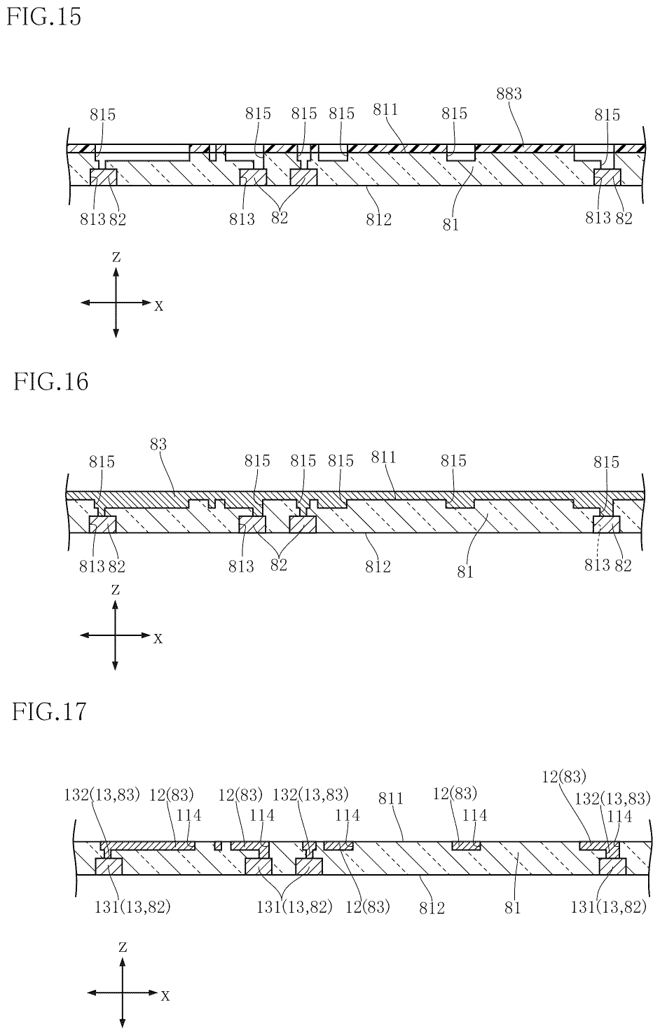

Next, as shown in FIG. 15, a plurality of third recesses 815 are formed in the base member 81. In the formation of the third recesses 815, a third mask layer 883 is formed first on the obverse surface 811 by lithographic patterning. Next, the third recesses 815 are formed to be recessed from the obverse surface 811 by reactive ion etching. Note that each of the second recesses 814 formed in the step shown in FIG. 14 will be a part of one of the third recesses 815. In this step, a third recess 815 including a part of a second recess 814 should connect to one of the first recesses 813. Finally, the third mask layer 883 is removed. This completes the formation of the third recesses 815. A part of each third recess 815 will be one of the recesses 114 of the substrate 11 in the semiconductor device A10.

Next, as shown in FIGS. 16 and 17, a plurality of wirings 12 are formed to be accommodated in the third recesses 815 of the base member 81. Further, a plurality of connecting wirings 13 are formed to be accommodated in the third recesses 815 and the first recesses 813 of the base member 81.

First, as shown in FIG. 16, a second metal layer 83 is formed to cover the obverse surface 811 of the base member 81 and the third recesses 815 of the base member 81. In the formation of the second metal layer 83, an underlying layer is formed first to cover the obverse surface 811, the surface of the base member 81 defining the third recesses 815, and the surfaces of the first metal layers 82 exposed from the third recesses 815. The underlying layer includes a thin metal film in contact with the base member 81 and the first metal layers 82 and made of titanium, and a thin metal film made of copper and formed on the thin metal film of titanium. The underlying layer is formed by sputtering. Then, a copper plating layer is formed by electrolytic plating with the underlying layer used as a conductive path. At this point, the dimension in the first direction z of the portion of the copper plating layer formed on the obverse surface 811 should be greater than or equal to a predetermined value. This completes the formation of the second metal layer 83.

Next, as shown in FIG. 17, the second metal layer 83 is ground by chemical mechanical polishing (CMP) until the entirety of the obverse surface 811 of the base member 81 is exposed. As a result, a plurality of wirings 12 each having an exposed surface 121 are formed. At the same time, a plurality of connecting wirings 13 are formed. In other words, the second metal layer 83 is ground to become the wirings 12 and the second portions 132 of the connecting wirings 13. The roughness of each of the exposed surfaces 121 of the wirings 12 and the obverse surface 811 is smaller than the roughness of the reverse surface 812 of the base member 81.

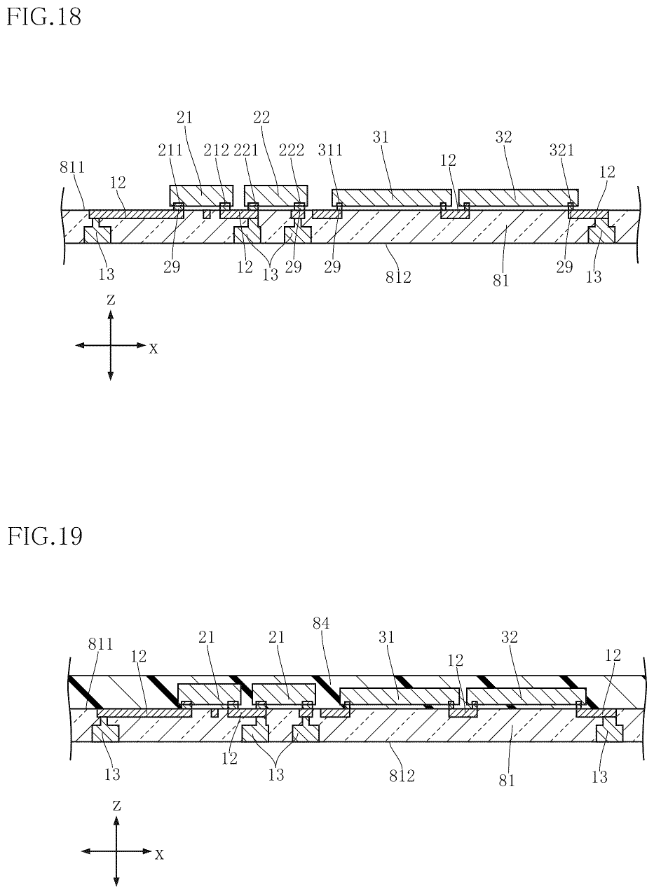

Next, as shown in FIG. 18, a plurality of: first semiconductor elements 21, a plurality of second semiconductor elements 22, a drive element 31, and a control element 32 are electrically bonded to the wirings 12. The following description on the method of electrical bonding is provided on the presumption that the bonding layer 29 is solder. In another example, Cu-Cu bonding may be employed to electrically bond the first semiconductor elements 21, the second semiconductor elements 22, the drive element 31, and the control element 32 to the wirings 12.

First, a flip chip bonder is used to temporarily attach the first electrode 211, the second electrode 212, and the two first gate electrodes 213 of each first semiconductor element 21 and the third electrode 221, the fourth electrode 222, and the two second gate electrodes 223 of each second semiconductor element 22 to the bonding layer 29. Next, the flip chip bonder is used to temporarily attach the electrodes 311 of the drive element 31 and the electrodes 321 of the control element 32 to the bonding layer 29. Next, the bonding layer 29 is melted by reflowing. Finally, the melted bonding layer 29 is solidified by cooling. As a result, the first electrode 211, the second electrode 212, and the two first gate electrodes 213 of each first semiconductor element 21 and the third electrode 221, the fourth electrode 222, and the two second gate electrodes 223 of each second semiconductor element 22 are electrically bonded to the wirings 12. At the same time, the electrodes 311 of the drive element 31 and the electrodes 321 of the control element 32 are electrically bonded to the wirings 12.

Next, as shown in FIG. 19, a molding resin 84 is formed to cover the wirings 12, the first semiconductor elements 21, the second semiconductor elements 22, the drive element 31, and the control element 32. The molding resin 84 comprises a plurality of sealing resins 40, including the sealing resin 40 of the semiconductor device A10, that are connected to each other in a direction perpendicular to the first direction z. The molding resin 84 is made of a material containing a black epoxy resin with fillers. The molding resin 84 is formed by compression molding. At this point, the molding resin 84 is formed to be in contact with the obverse surface 811 of the base member 81.

Next, as shown in FIG. 20, a plurality of terminals 50 are formed to cover the respective connecting wirings 13 exposed from the reverse surface 812 of the base member 81. The terminals 50 are formed by electroless plating.

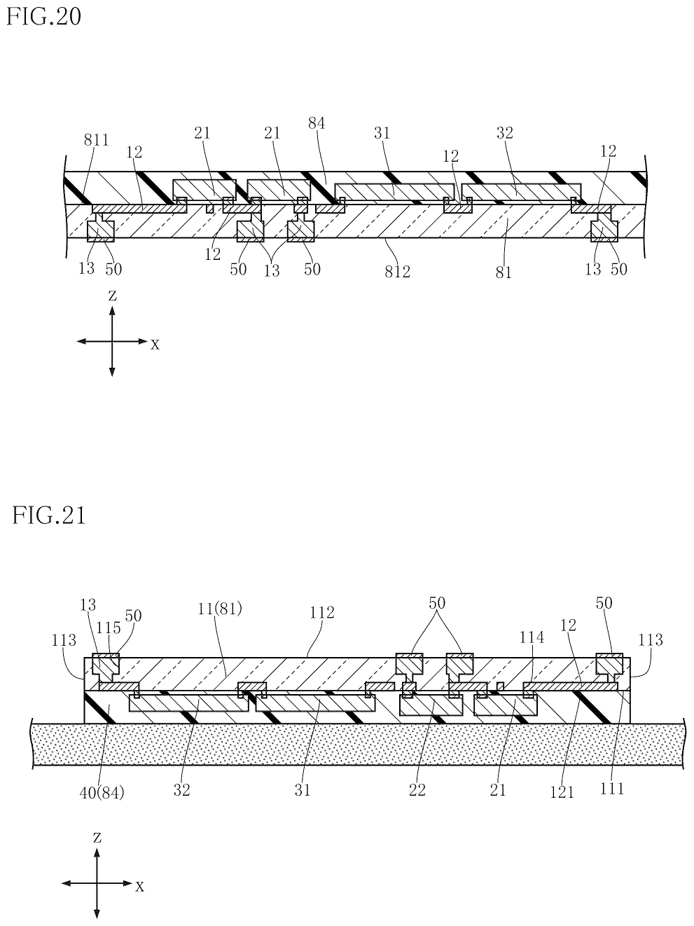

Finally, as shown in FIG. 21, a tape 89 is attached to the surface of the molding resin 84 facing in the first direction z, and the base member 81 and the molding resin 84 are cut along the grid lines in the second direction x and the third direction y so that they are divided into individual pieces. The cutting is performed with a dicing blade, for example. An individual piece of the base member 81 and an individual piece of the molding resin 84, which are obtained by the cutting, serve as the substrate 11 and the sealing resin 40 of the semiconductor device A10, respectively. The semiconductor device A10 is obtained through the steps described above.

### Variation

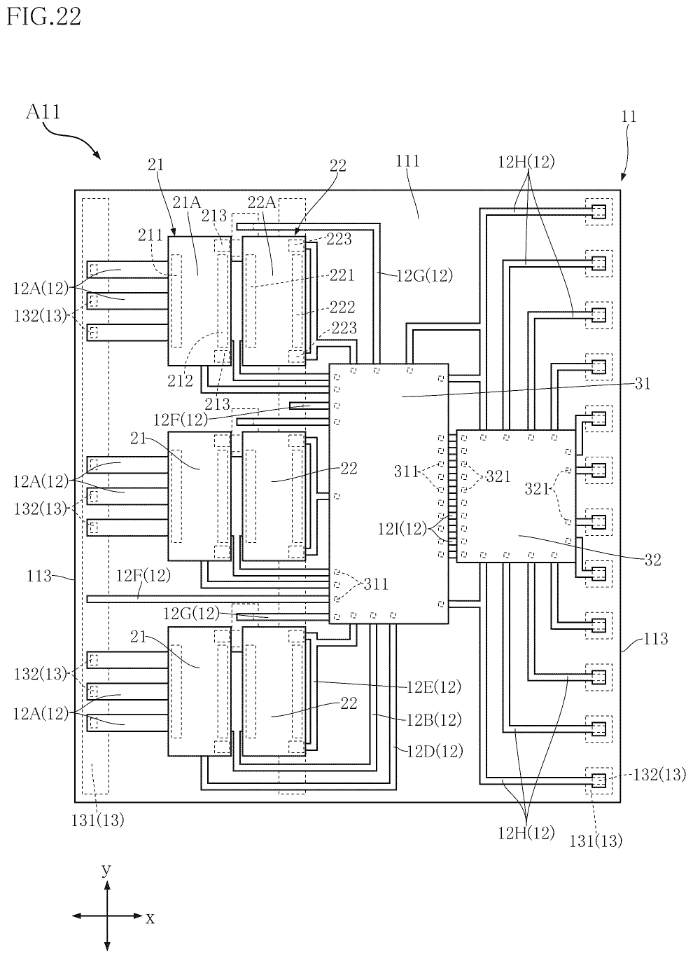

Next, a semiconductor device All, which is a variation of the semiconductor device A10, will be described with reference to FIG. 22. For convenience of understanding, FIG. 22 omits the sealing resin 40.

As shown in FIG. 22, the semiconductor device All is different from the semiconductor device A10 in the configuration of the first wirings 12A of the wirings 12. Each of the first wirings 12A is divided into a plurality of areas. The areas extend in the second direction x. The areas are spaced apart from each other in the third direction y.

The following describes advantages of the semiconductor device A10.

The semiconductor device A10 includes the substrate 11 having the obverse surface 111 and the reverse surface 112, a first semiconductor element 21 having a first electrode 211 and a second electrode 212, and wirings 12 each including a portion located between the substrate 11 and one of the first electrode 211 and the second electrode 212. The first electrode 211 and the second electrode 212 are electrically bonded to the respective wirings 12. The substrate 11 is formed with recesses 114 recessed from the obverse surface 111. The wirings 12 are accommodated in the recesses 114. Each of the wirings 12 has an exposed surface 121 that is flush with the obverse surface 111. The roughness of the exposed surface 121 is smaller than the roughness of the reverse surface 112. This configuration reduces the loss of a current flowing near the exposed surface 121 of each wiring 12. Of the currents flowing through each wiring 12, a current having a relatively high signal frequency flows near the exposed surface 121. As such, the wirings 12 can smoothly pass a current contributing to high-frequency transmission. Thus, according to this configuration, it is possible to suppress a transmission loss related to high-frequency transmission inside the semiconductor device A10.

The exposed surface 121 of each wiring 12 in the semiconductor device A10 is formed during the step of forming the wirings 12 shown in FIG. 17 in the manufacturing process of the semiconductor device A10, and is obtained by grinding the second metal layer 83 by chemical mechanical polishing until the entire obverse surface 811 of the base member 81 is exposed. As a result, the roughness of each of the exposed surfaces 121 and the obverse surface 111 of the substrate 11 is smaller than the roughness of the reverse surface 112 of the substrate 11.

The wirings 12 are accommodated in the recesses 114 of the substrate 11. This configuration allows a reduction in the dimension of the semiconductor device A10 in the first direction z.

The semiconductor device A10 further includes connecting wirings 13, and at least a portion of each connecting wiring 13 is accommodated in the substrate 11. The connecting wirings 13 are connected to the respective wirings 12 and exposed from the reverse surface 112 of the substrate 11. With this configuration, even when the wirings 12 are entirely covered with the sealing resin 40, a conductive path from the wirings 12 to the wiring board on which the semiconductor device A10 is mounted can be reliably provided without increasing the dimensions of the semiconductor device A10.

Each of the connecting wirings 13 has a first portion 131 and a second portion 132 located between the first portion 131 and a wiring 12 in the first direction z. As viewed in the first direction z, the area of the first portion 131 is larger than the area of the second portion 132. When the semiconductor device A10 is in use, the heat generated from the first semiconductor element 21 is conducted to the wirings 12. The heat conducted to the wirings 12 is then conducted to the connecting wirings 13. This configuration reduces the thermal resistance of the connecting wirings 13 in the first direction z, allowing the heat conducted to the connecting wirings 13 to be promptly released to the outside.

### Second Embodiment

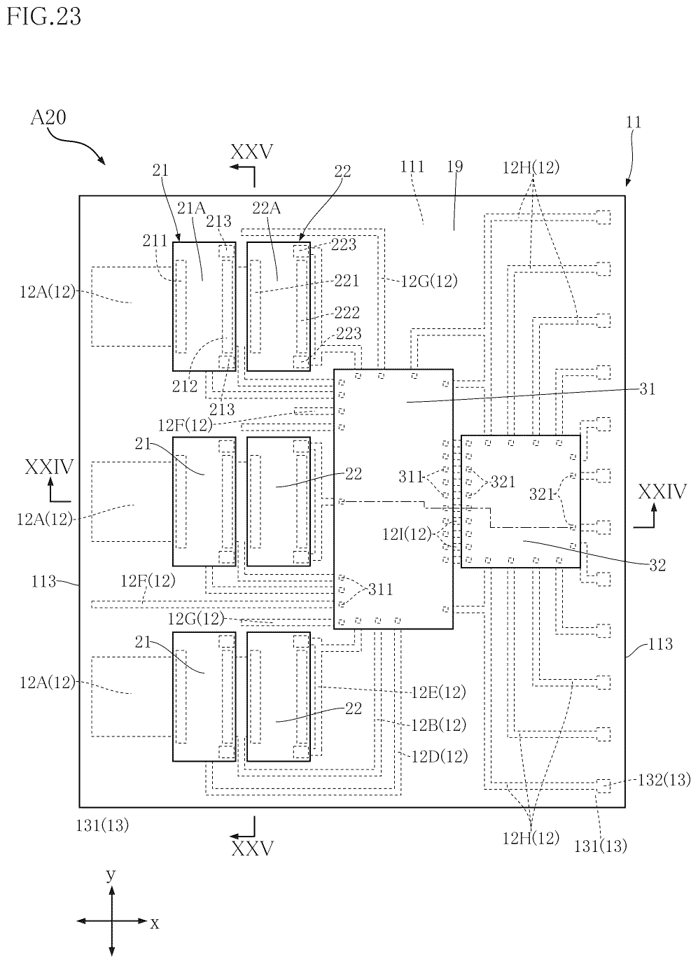

With reference to FIGS. 23 to 25, a semiconductor device A20 according to a second embodiment of the present disclosure will be described. In these figures, elements that are the same as or similar to the elements of the semiconductor device A10 described above are provided with the same reference numerals, and descriptions thereof are omitted. For convenience of understanding, FIG. 23 omits the sealing resin 40.

The semiconductor device A20 is different from the semiconductor device A10 in further including an insulating layer 19.

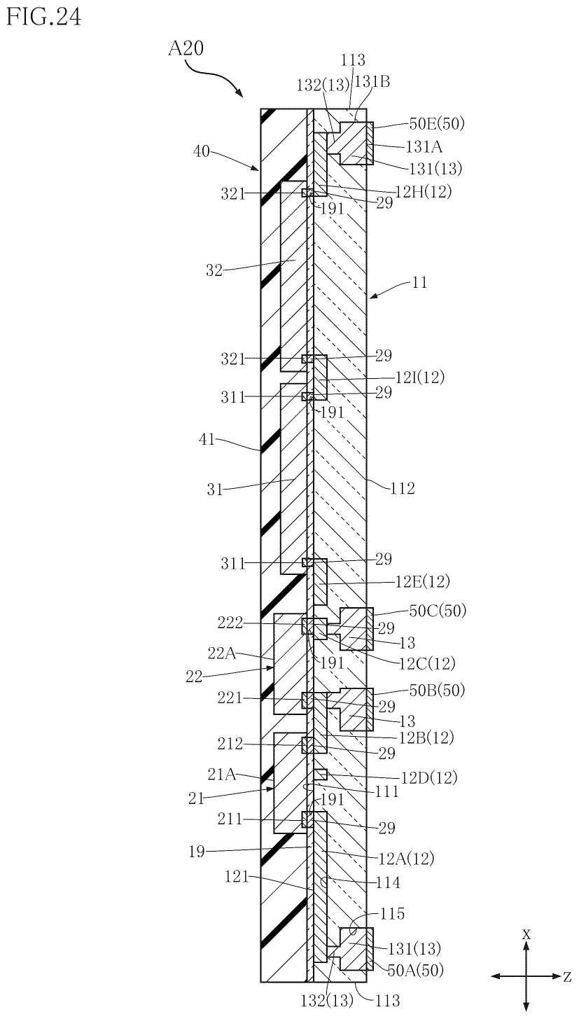

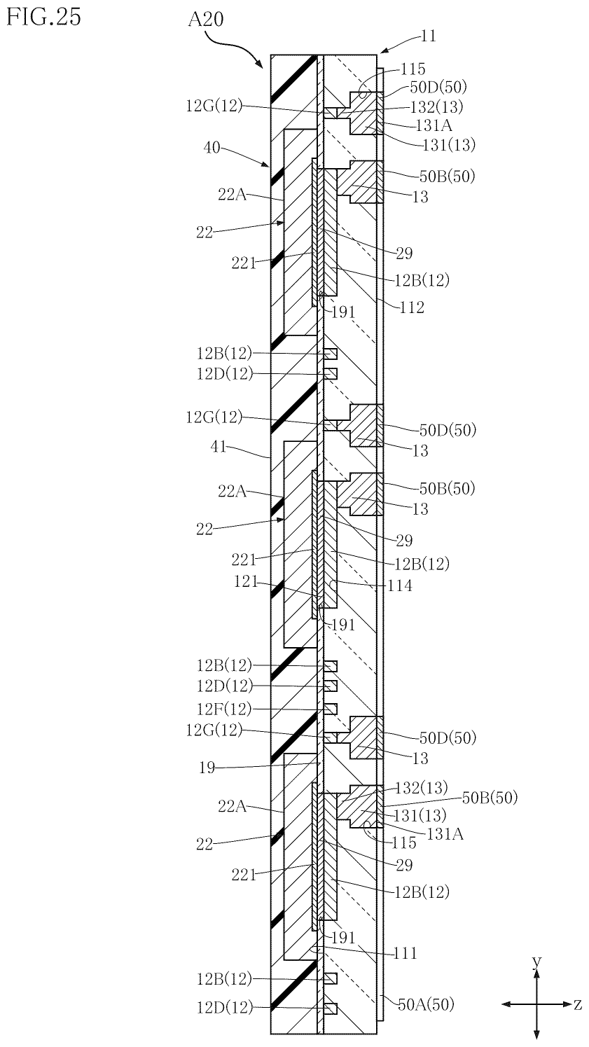

As shown in FIGS. 24 and 25, the insulating layer 19 includes a portion located between each of the obverse surface 111 of the substrate 11 and the exposed surfaces 121 of the wirings 12 and each of the first semiconductor elements 21, the second semiconductor elements 22, the drive element 31 and the control element 32. The dimension of the insulating layer 19 in the first direction z is smaller than the dimension of the sealing resin 40 in the first direction z. As shown in FIG. 23, the insulating layer 19 covers the obverse surface 111 and the exposed surfaces 121 of the wirings 12. The composition of the insulating layer 19 includes silicon dioxide, for example. In another example, the composition of the insulating layer 19 may include silicon nitride (Si₃N₄). The insulating layer 19 is formed by plasma CVD (Chemical Vapor Deposition) under a relatively low temperature condition.

As shown in FIGS. 24 and 25, the insulating layer 19 is formed with a plurality of openings 191 that penetrate in the first direction z. The openings 191 accommodate the bonding layer 29. The insulating layer 19 includes a portion located between each of the wirings 12 and each of the first semiconductor elements 21, the second semiconductor elements 22, the drive element 31, and the control element 32. In the semiconductor device A20, the first semiconductor elements 21, the second semiconductor elements 22, the drive element 31, and the control element 32 are in contact with the insulating layer 19.

The following describes advantages of the semiconductor device A20.

The semiconductor device A20 includes the substrate 11 having the obverse surface 111 and the reverse surface 112, a first semiconductor element 21 having a first electrode 211 and a second electrode 212, and wirings 12 each including a portion located between the substrate 11 and one of the first electrode 211 and the second electrode 212. The first electrode 211 and the second electrode 212 are electrically bonded to the respective wirings 12. The substrate 11 is formed with recesses 114 recessed from the obverse surface 111. The wirings 12 are accommodated in the recesses 114. Each of the wirings 12 has an exposed surface 121 that is flush with the obverse surface 111. The roughness of the exposed surface 121 is smaller than the roughness of the reverse surface 112. Thus, with this configuration, the semiconductor device A20 can also suppress a transmission loss related to high-frequency transmission inside the semiconductor device A20. Further, the semiconductor device A20 has advantages similar to those of the semiconductor device A10 owing to its common configuration with the semiconductor device A10.

The semiconductor device A20 further includes the insulating layer 19 located between each of the obverse surface 111 of the substrate 11 and the exposed surfaces 121 of the wirings 12 and the first semiconductor element 21. This configuration prevents a gap from being formed between each of the wirings 12 and the first semiconductor element 21, as compared to the configuration of the semiconductor device A10. This makes it possible to improve the dielectric strength of the semiconductor device A20.

The insulating layer 19 is formed with the openings 191 that penetrate in the first direction z. The openings 191 accommodate the bonding layer 29. With this configuration, when the first electrode 211 and the second electrode 212 of the first semiconductor element 21 are electrically bonded to the wirings 12 by soldering, the melted bonding layer 29 is dammed in the openings 191. Note that the exposed surfaces 121 of the wirings 12 are relatively smooth. This facilitates wetting and spreading of the melted bonding layer 29 on the exposed surfaces 121. This advantageous effect compensates for the shortcomings of the present disclosure.

In addition, the effect of self-alignment of the melted bonding layer 29 can be further improved by the melted bonding layer 29 making contact with the surfaces that define the openings 191.

### Third Embodiment

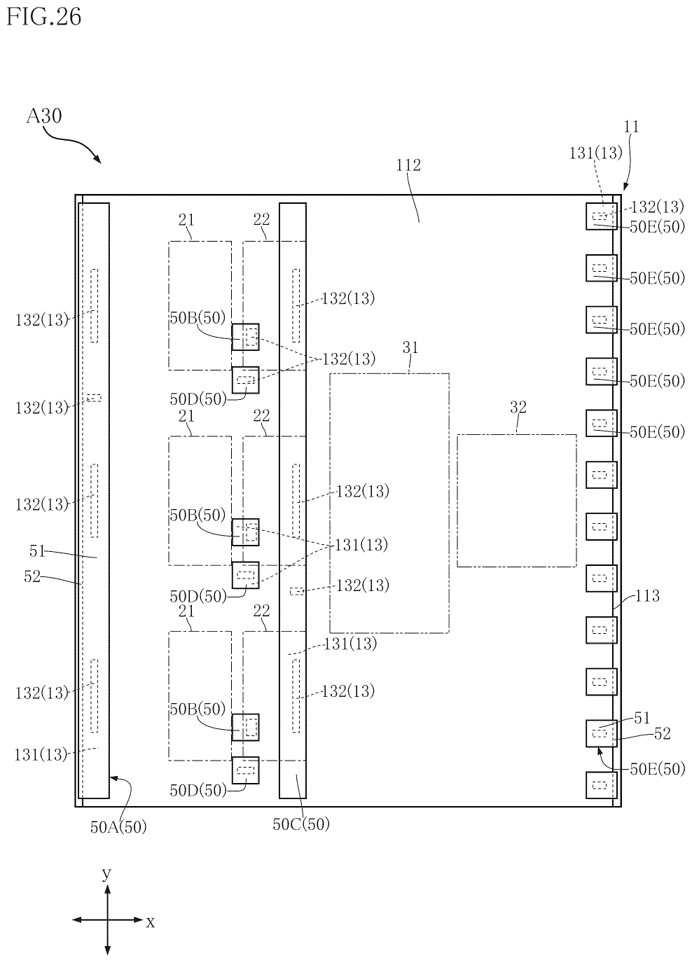

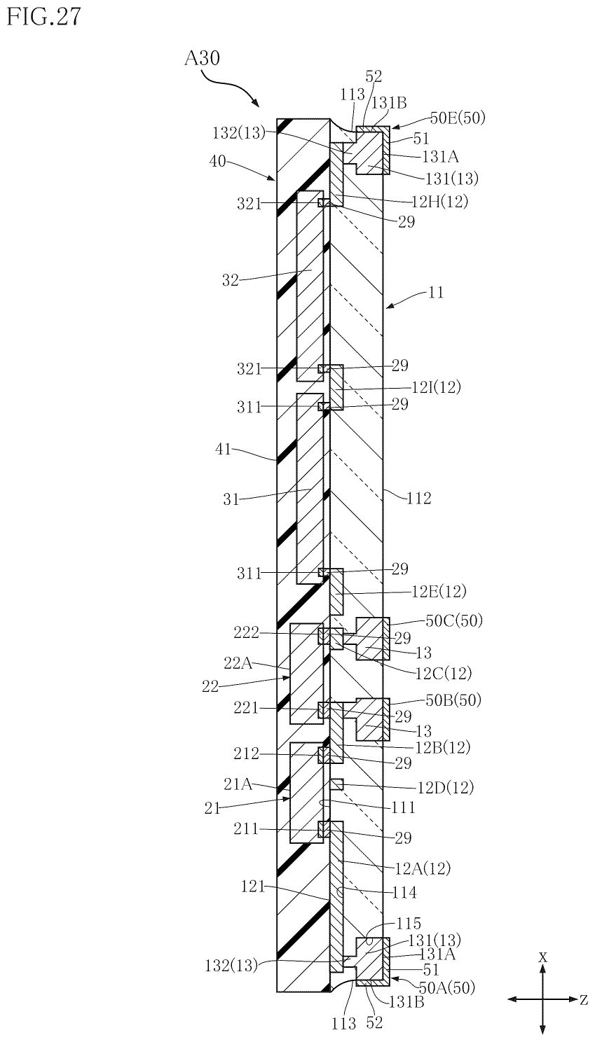

With reference to FIGS. 26 and 27, a semiconductor device A30 according to a third embodiment of the present disclosure will be described. In these figures, elements that are the same as or similar to the elements of the semiconductor device A10 described above are provided with the same reference numerals, and descriptions thereof are omitted. The cross- section shown in FIG. 27 is taken along the same line as the cross-section of the semiconductor device A10 shown in FIG. 5.

The semiconductor device A30 is different from the semiconductor device A10 in the configurations of the connecting wirings 13 and the terminals 50.

As shown in FIG. 27, of the plurality of connecting wirings 13, the second end surfaces 131B of the connecting wirings 13 connected to the first wirings 12A are exposed from one of the two side surfaces 113 of the substrate 11. Of the plurality of connecting wirings 13, the second end surfaces 131B of the connecting wirings 13 connected to the control wirings 12H are exposed from the other one of the two side surfaces 113 of the substrate 11.

As shown in FIGS. 26 and 27, the first terminal 50A and the control terminals 50E of the terminals 50 each have a bottom portion 51 and a side portion 52. Each of the bottom portions 51 is located on the opposite side from the wirings 12 with respect to the connecting wirings 13 in the first direction z. Each of the bottom portions 51 covers the first end surface 131A of one of the connecting wirings 13 exposed from the reverse surface 112 of the substrate 11. Each of the side portions 52 extends from the corresponding bottom portion 51 in the first direction z. Each of the side portions 52 covers the second end surface 131B of one of the connecting wirings 13 that is exposed from one of the two side surfaces 113 of the substrate 11.

The following describes advantages of the semiconductor device A30.

The semiconductor device A30 includes the substrate 11 having the obverse surface 111 and the reverse surface 112, a first semiconductor element 21 having a first electrode 211 and a second electrode 212, and wirings 12 each including a portion located between the substrate 11 and one of the first electrode 211 and the second electrode 212. The first electrode 211 and the second electrode 212 are electrically bonded to the respective wirings 12. The substrate 11 is formed with recesses 114 recessed from the obverse surface 111. The wirings 12 are accommodated in the recesses 114. Each of the wirings 12 has an exposed surface 121 that is flush with the obverse surface 111. The roughness of the exposed surface 121 is smaller than the roughness of the reverse surface 112. Thus, with this configuration, the semiconductor device A30 can also suppress a transmission loss related to transmission the high-frequency inside semiconductor device A30. Further, the semiconductor device A30 has advantages similar to those of the semiconductor device A10 owing to its common configuration with the semiconductor device A10.

The semiconductor device A30 includes a terminal 50 having a bottom portion 51 and a side portion 52. When the semiconductor device A30 having this configuration is mounted on a wiring board, melted solder adheres to the side portion 52. This facilitates the formation of a solder fillet. This makes it possible to improve the bonding strength of the semiconductor device A30 to the wiring board. In addition, the solder adhering to the side portion 52 is readily visible and therefore enables visual inspection of the bonding state of the semiconductor device A30 with respect to the wiring board.

### Fourth Embodiment

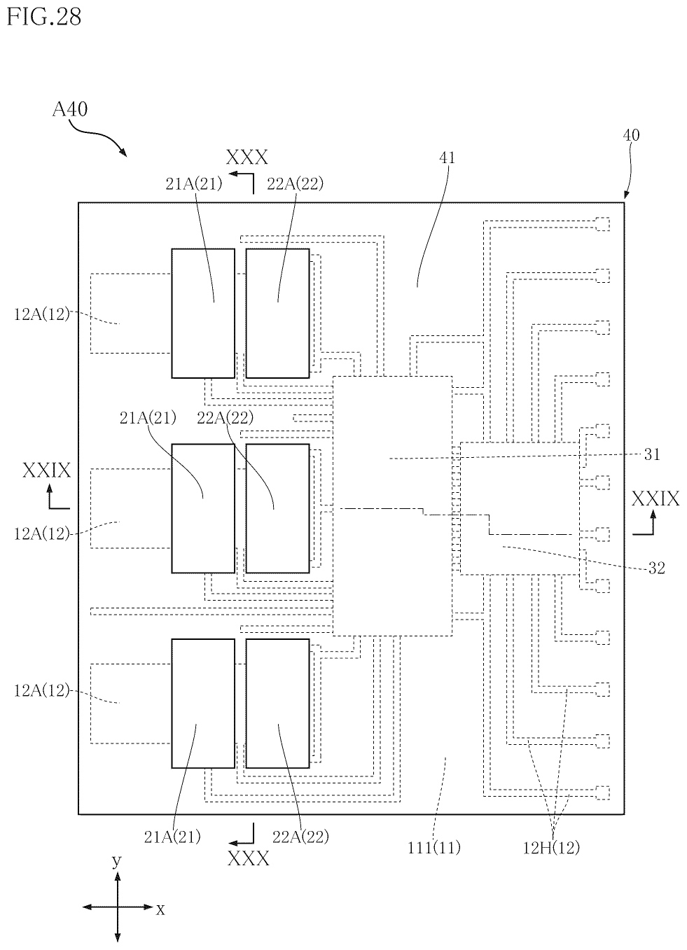

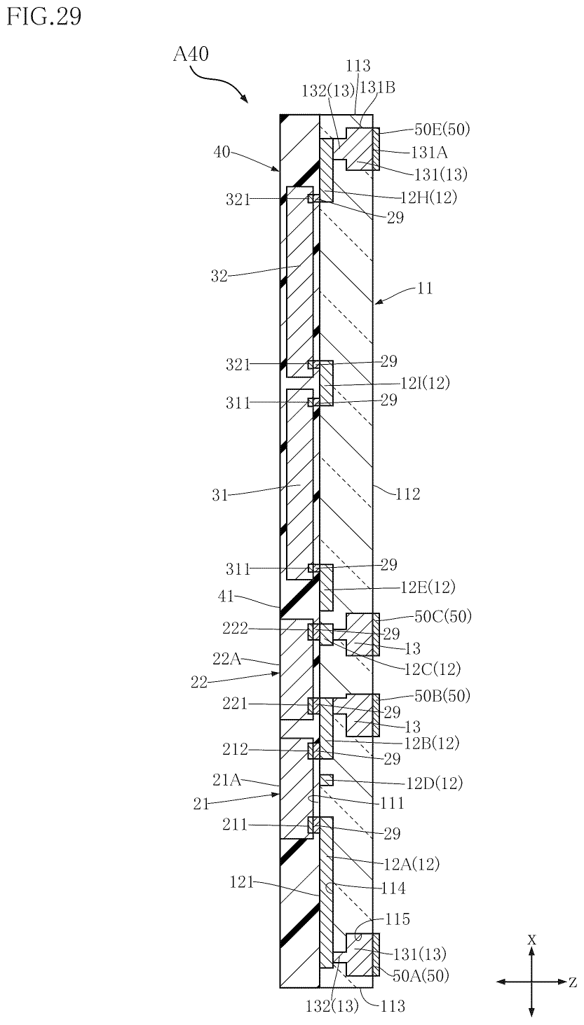

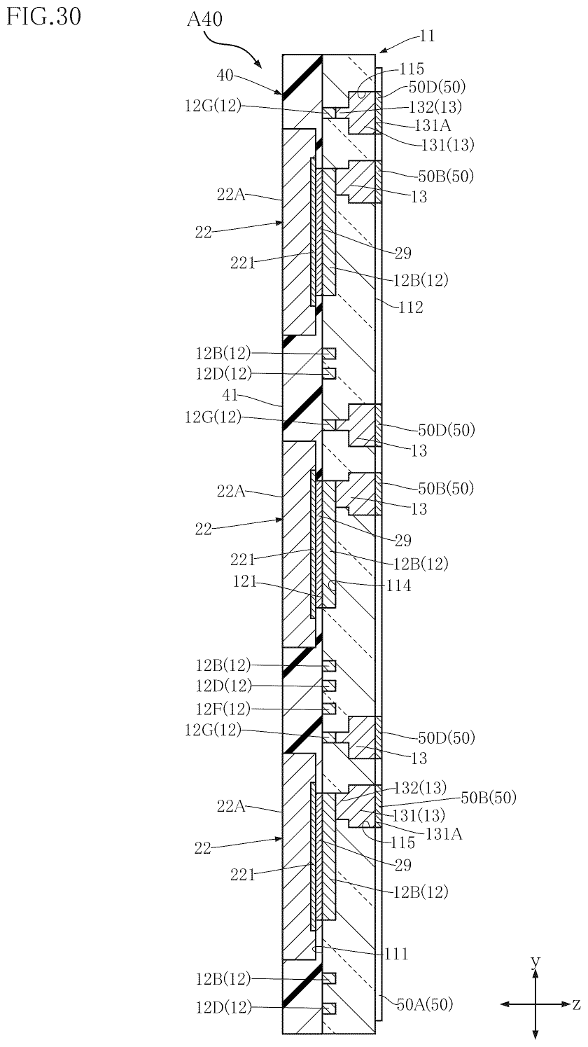

With reference to FIGS. 28 to 30, a semiconductor device A40 according to a fourth embodiment of the present disclosure will be described. In these figures, elements that are the same as or similar to the elements of the semiconductor device A10 described above are provided with the same reference numerals, and descriptions thereof are omitted.

The semiconductor device A40 is different from the semiconductor device A10 in the configurations of the first semiconductor elements 21 and the second semiconductor elements 22.

As shown in FIGS. 28 to 30, the first upper surface 21A of each first semiconductor element 21 and the second upper surface 22A of each second semiconductor element 22 are exposed from the top surface 41 of the sealing resin 40 to the outside. The first upper surface 21A and the second upper surface 22A are flush with the top surface 41. Thus, the dimension of the sealing resin 40 in the first direction z is smaller than the dimension of the sealing resin 40 in the semiconductor device A10 in the first direction z.

The following describes advantages of the semiconductor device A40.

The semiconductor device A40 includes the substrate 11 having the obverse surface 111 and the reverse surface 112, a first semiconductor element 21 having a first electrode 211 and a second electrode 212, and wirings 12 each including a portion located between the substrate 11 and one of the first electrode 211 and the second electrode 212. The first electrode 211 and the second electrode 212 are electrically bonded to the respective wirings 12. The substrate 11 is formed with recesses 114 recessed from the obverse surface 111. The wirings 12 are accommodated in the recesses 114. Each of the wirings 12 has an exposed surface 121 that is flush with the obverse surface 111. The roughness of the exposed surface 121 is smaller than the roughness of the reverse surface 112. Thus, with this configuration, the semiconductor device A40 can also suppress a transmission loss related to transmission inside high-frequency the semiconductor device A40. Further, the semiconductor device A40 has advantages similar to those of the semiconductor device A10 owing to its common configuration with the semiconductor device A10.

In the semiconductor device A40, the first semiconductor element 21 is exposed from the top surface 41 of the sealing resin 40 to the outside. When the semiconductor device A40 having this configuration is in use, the heat generated from the first semiconductor element 21 can be efficiently released to the outside. Further, since the first upper surface 21A of the first semiconductor element 21 is flush with the top surface 41, it is possible to reduce the dimension of the sealing resin 40 in the first direction z. This contributes to the size reduction of the semiconductor device A40.

### Fifth Embodiment

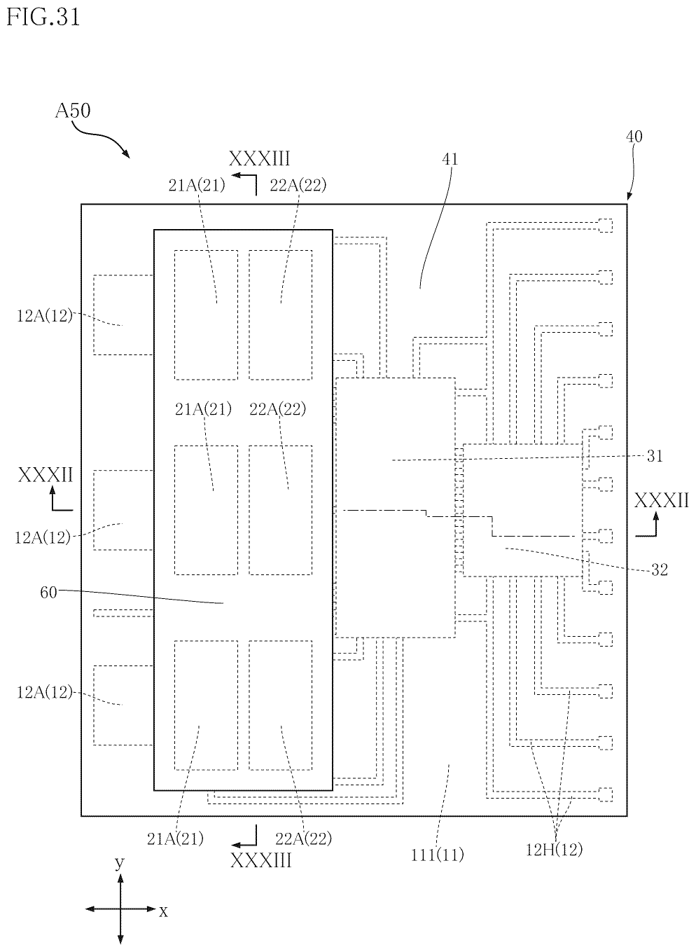

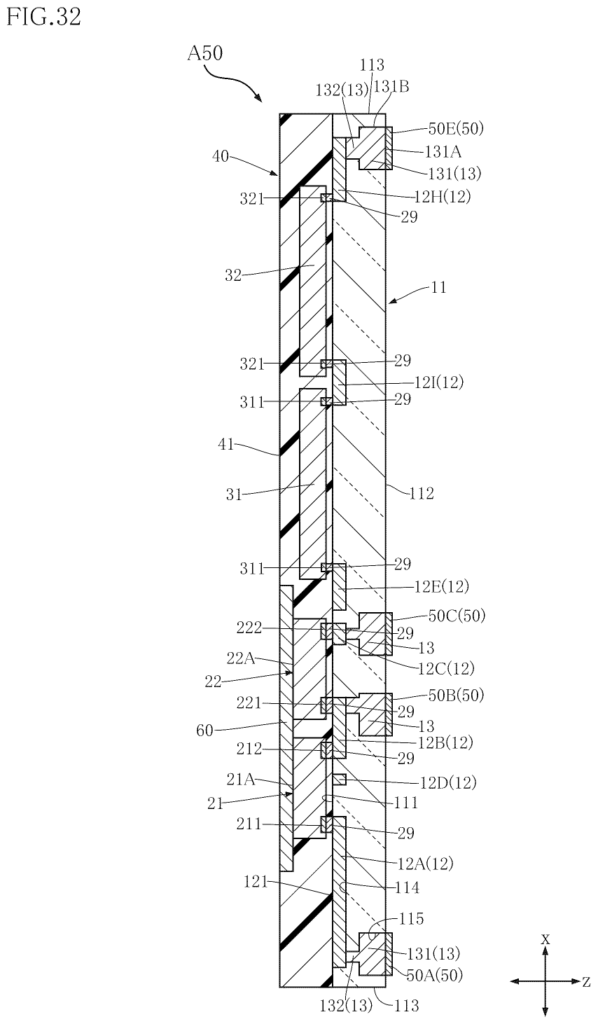

With reference to FIGS. 31 to 33, a semiconductor device A50 according to a fifth embodiment of the present disclosure will be described. In these figures, elements that are the same as or similar to the elements of the semiconductor device A10 described above are provided with the same reference numerals, and descriptions thereof are omitted.

The semiconductor device A50 is different from the semiconductor device A10 in further including a heat dissipation layer 60.

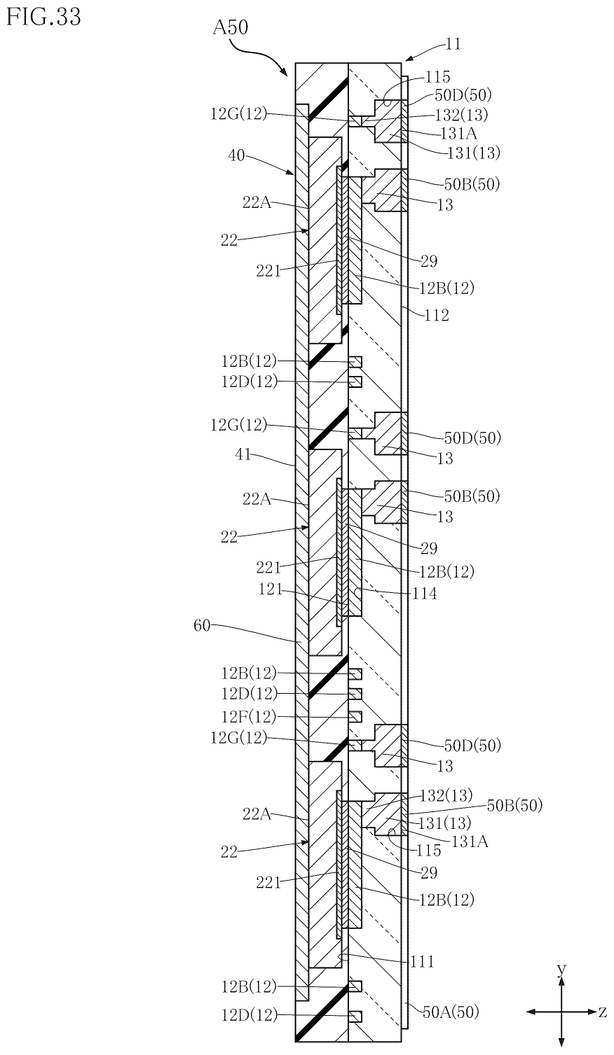

As shown in FIGS. 32 and 33, the heat dissipation layer 60 is located on the opposite side from the substrate 11 with respect to the first semiconductor elements 21 and the second semiconductor elements 22. The heat dissipation layer 60 is in contact with the first upper surface 21A of each first semiconductor element 21 and the second upper surface 22A of each second semiconductor element 22. As shown in FIGS. 31 to 33, the heat dissipation layer 60 is exposed from the top surface 41 of the sealing resin 40 to the outside. As viewed in the first direction z, the periphery of the heat dissipation layer 60 surrounds the first semiconductor elements 21 and the second semiconductor elements 22. The composition of the heat dissipation layer 60 includes copper, for example.

The following describes advantages of the semiconductor device A50.

The semiconductor device A50 includes the substrate 11 having the obverse surface 111 and the reverse surface 112, a first semiconductor element 21 having a first electrode 211 and a second electrode 212, and wirings 12 each including a portion located between the substrate 11 and one of the first electrode 211 and the second electrode 212. The first electrode 211 and the second electrode 212 are electrically bonded to the respective wirings 12. The substrate 11 is formed with recesses 114 recessed from the obverse surface 111. The wirings 12 are accommodated in the recesses 114. Each of the wirings 12 has an exposed surface 121 that is flush with the obverse surface 111. The roughness of the exposed surface 121 is smaller than the roughness of the reverse surface 112. Thus, with this configuration, the semiconductor device A50 can also suppress a transmission loss related to high-frequency transmission inside the semiconductor device A50. Further, the semiconductor device A50 has advantages similar to those of the semiconductor device A10 owing to its common configuration with the semiconductor device A10.

The semiconductor device A50 further includes the heat dissipation layer 60 located on the opposite side from the substrate 11 with respect to the first semiconductor element 21 in the first direction z. The heat dissipation layer 60 is in contact with the first semiconductor elements 21. The heat dissipation layer 60 is exposed from the sealing resin 40 to the outside. When the semiconductor device A50 having this configuration is in use, the heat generated from the first semiconductor element 21 is conducted to the heat dissipation layer 60. The heat conducted to the heat dissipation layer 60 is diffused in a direction perpendicular to the first direction z. Thus, the semiconductor device A50 can release the heat generated from the first semiconductor element 21 to the outside more efficiently than the semiconductor device A40.

The present disclosure is not limited to the above embodiments. Various design changes can be made to the specific configurations of the elements of the present disclosure.

The present disclosure includes the embodiments according to the following clauses.

### Clause 1.

A semiconductor device comprising:
a substrate including an obverse surface and a reverse surface facing away from each other in a first direction;
a first semiconductor element including a first electrode and a second electrode; and
a wiring including a portion located between the substrate and each of the first electrode and the second electrode,
wherein the first electrode and the second electrode are electrically bonded to the wiring,
the substrate is formed with a recess recessed from the obverse surface,
the wiring is accommodated in the recess,
the wiring includes an exposed surface that is flush with the obverse surface, and
a roughness of the exposed surface is smaller than a roughness of the reverse surface.

### Clause 2.

The semiconductor device according to clause 1, wherein a roughness of the obverse surface is smaller than the roughness of the reverse surface.

### Clause 3.

The semiconductor device according to clause 2, further comprising a sealing resin covering at least a portion of the first semiconductor element,
wherein as viewed in the first direction, the sealing resin overlaps with the obverse surface and the exposed surface.

### Clause 4.

The semiconductor device according to clause 3, wherein the sealing resin is in contact with the obverse surface and the exposed surface.

### Clause 5.

The semiconductor device according to clause 3, further comprising: an insulating layer located between each of the obverse surface and the exposed surface and the first semiconductor element,
wherein a dimension of the insulating layer in the first direction is smaller than a dimension of the sealing resin in the first direction.

### Clause 6.

The semiconductor device according to any of clauses 1 to 5, further comprising a connecting wiring at least partially accommodated in the substrate,
wherein the connecting wiring is connected to the wiring, and
the connecting wiring is exposed from the reverse surface.

### Clause 7.

The semiconductor device according to clause 6, wherein the connecting wiring and the wiring are in contact with the substrate.

### Clause 8.

The semiconductor device according to clause 7, wherein a composition of the substrate includes silicon dioxide.

### Clause 9.

The semiconductor device according to clause 7 or 8,
wherein the connecting wiring includes a first portion and a second portion located between the first portion and
the wiring in the first direction,
the first portion is exposed from the reverse surface,
the second portion is connected to the wiring, and as viewed in the first direction, an area of the first portion is larger than an area of the second portion.

### Clause 10.

The semiconductor device according to clause 6, further comprising a terminal covering the connecting wiring and exposed to an outside.

### Clause 11.

The semiconductor device according to clause 10, wherein as viewed in the first direction, the connecting wiring and the wiring are surrounded by a periphery of the obverse surface.

### Clause 12.

The semiconductor device according to clause 10,
wherein the terminal includes a bottom portion and a side portion,
the bottom portion is located on an opposite side from the wiring with respect to the connecting wiring in the first direction, and
the side portion extends from the bottom portion in the first direction.

### Clause 13.

The semiconductor device according to any of clauses 3 to 5,
wherein the sealing resin includes a top surface facing a same side as the obverse surface in the first direction, and
the first semiconductor element is exposed from the top surface to an outside.

### Clause 14.

The semiconductor device according to any of clauses 3 to 5, further comprising a heat dissipation layer located on an opposite side from the substrate with respect to the first semiconductor element in the first direction,
wherein the heat dissipation layer is in contact with the first semiconductor element, and
the heat dissipation layer is exposed from the sealing resin.

### Clause 15.

The semiconductor device according to any of clauses 1 to 5, further comprising a second semiconductor element electrically connected to the second electrode,
wherein the second semiconductor element is spaced apart from the first semiconductor element in a second direction perpendicular to the first direction.

### Clause 16.

The semiconductor device according to clause 15,
wherein the wiring includes a first wiring electrically bonded to the first electrode,
the first wiring is divided into a plurality of areas, and
the plurality of areas extend in the second direction and are spaced apart from each other in a third direction perpendicular to the first direction and the second direction.

### Clause 17.

The semiconductor device according to clause 15, further comprising a drive element electrically connected to the first semiconductor element and the second semiconductor element, and a control element electrically connected to the drive element,
wherein the drive element and the control element are located on an opposite side from the first semiconductor element with respect to the second semiconductor element in the second direction.

### Clause 18.

A method for manufacturing a semiconductor device, comprising the steps of:

forming a recess in a base member including an obverse surface, the recess being recessed from the obverse surface;
forming a wiring to be accommodated in the recess; and
electrically bonding a first semiconductor element to the wiring,
wherein the first semiconductor element includes a first electrode and a second electrode that face the obverse surface,
the step of electrically bonding the first semiconductor element includes electrically bonding the first electrode and the second electrode to the wiring, and
the step of forming the wiring includes forming a metal layer covering the recess and the obverse surface and grinding the metal layer by chemical mechanical polishing until an entirety of the obverse surface is exposed.

REFERENCE NUMERALS

A10, A20, A30, A40, A50: Semiconductor device

| | | |
|---|---|---|
| 11: Substrate | 111: Obverse surface | |
| 112: Reverse surface | 113: Side surface | |
| 114: Recess | 115: Through-hole | |
| 12: Wiring | 12A: First wiring | |
| 12B: Second wiring | 12C: Third wiring | |
| 12D: First gate wiring | 12E: Second gate wiring | |
| 12F: Detection wiring | 12G: Boot wiring | |
| 12H: Control wiring | 12I: Relay wiring | |
| 121: Exposed surface | 13: Connecting wiring | |
| 131: First portion | 131A: First end surface | |
| 131B: Second end surface | 132: Second portion | |
| 19: Insulating layer | 191: Opening | |
| 21: First semiconductor element | 21A: First upper surface | |
| 211: First electrode | 212: Second electrode | |
| 213: First gate electrode | 22: Second semiconductor element | |
| 22A: Second upper surface | 221: Third electrode | |
| 222: Fourth electrode | 223: Second gate electrode | |
| 29: Bonding layer | 31: Drive element | |
| 311: Electrode | 32: Control element | |
| 321: Electrode | 40: Sealing resin | |
| 41: Top surface | 50: Terminal | |
| 50A: First terminal | 50B: Second terminal | |
| 50C: Third terminal | 50D: Boot terminal | |
| 50E: Control terminal | 51: Bottom portion | |
| 52: Side portion | 60: Heat dissipation layer | |
| 81: Base member | 811: Obverse surface | |
| 812: Reverse surface | 813: First recess | |
| 814: Second recess | 815: Third recess | |
| 82: First metal layer | 83: Second metal layer | |
| 84: Molding resin | 881: First mask layer | |
| 882: Second mask layer | 883: Third mask layer | 89: Tape |
| z: First direction | x: Second direction | y: Third direction |

1. A semiconductor device comprising:
a substrate including an obverse surface and a reverse surface facing away from each other in a first direction;
a first semiconductor element including a first electrode and a second electrode; and
a wiring including a portion located between the substrate and each of the first electrode and the second electrode,
wherein the first electrode and the second electrode are electrically bonded to the wiring,
the substrate is formed with a recess recessed from the obverse surface,
the wiring is accommodated in the recess,
the wiring includes an exposed surface that is flush with the obverse surface, and
a roughness of the exposed surface is smaller than a roughness of the reverse surface.

2. The semiconductor device according to claim 1, wherein a roughness of the obverse surface is smaller than the roughness of the reverse surface.

3. The semiconductor device according to claim 2, further comprising a sealing resin covering at least a portion of the first semiconductor element,
wherein as viewed in the first direction, the sealing resin overlaps with the obverse surface and the exposed surface.

4. The semiconductor device according to claim 3, wherein the sealing resin is in contact with the obverse surface and the exposed surface.

5. The semiconductor device according to claim 3, further comprising an insulating layer located between each of the obverse surface and the exposed surface and the first semiconductor element, and
wherein a dimension of the insulating layer in the first direction is smaller than a dimension of the sealing resin in the first direction.

6. The semiconductor device according to claim 1, further comprising a connecting wiring at least partially accommodated in the substrate,
wherein the connecting wiring is connected to the wiring, and
the connecting wiring is exposed from the reverse surface.

7. The semiconductor device according to claim 6, wherein the connecting wiring and the wiring are in contact with the substrate.

8. The semiconductor device according to claim 7, wherein a composition of the substrate includes silicon dioxide.

9. The semiconductor device according to claim 7,
wherein the connecting wiring includes a first portion and a second portion located between the first portion and the wiring in the first direction,
the first portion is exposed from the reverse surface,
the second portion is connected to the wiring, and
as viewed in the first direction, an area of the first portion is larger than an area of the second portion.

10. The semiconductor device according to claim 6, further comprising a terminal covering the connecting wiring and exposed to an outside.

11. The semiconductor device according to claim 10, wherein as viewed in the first direction, the connecting wiring and the wiring are surrounded by a periphery of the obverse surface.

12. The semiconductor device according to claim 10,
wherein the terminal includes a bottom portion and a side portion,
the bottom portion is located on an opposite side from the wiring with respect to the connecting wiring in the first direction, and
the side portion extends from the bottom portion in the first direction.

13. The semiconductor device according to claim 3,
wherein the sealing resin includes a top surface facing a same side as the obverse surface in the first direction, and
the first semiconductor element is exposed from the top surface to an outside.

14. The semiconductor device according to claim 3, further comprising a heat dissipation layer located on an opposite side from the substrate with respect to the first semiconductor element in the first direction,
wherein the heat dissipation layer is in contact with the first semiconductor element, and
the heat dissipation layer is exposed from the sealing resin.

15. The semiconductor device according to claim 1, further comprising a second semiconductor element electrically connected to the second electrode,
wherein the second semiconductor element is spaced apart from the first semiconductor element in a second direction perpendicular to the first direction.

16. The semiconductor device according to claim 15,
wherein the wiring includes a first wiring electrically bonded to the first electrode,
the first wiring is divided into a plurality of areas, and
the plurality of areas extend in the second direction and are spaced apart from each other in a third direction perpendicular to the first direction and the second direction.

17. The semiconductor device according to claim 15, further comprising a drive element electrically connected to the first semiconductor element and the second semiconductor element, and a control element electrically connected to the drive element,
wherein the drive element and the control element are located on an opposite side from the first semiconductor element with respect to the second semiconductor element in the second direction.

18. A method for manufacturing a semiconductor device, comprising:
forming a recess in a base member including an obverse surface, the recess being recessed from the obverse surface;
forming a wiring to be accommodated in the recess; and
electrically bonding a first semiconductor element to the wiring,
wherein the first semiconductor element includes a first electrode and a second electrode that face the obverse surface,
the electrically bonding the first semiconductor element includes electrically bonding the first electrode and the second electrode to the wiring, and
the forming the wiring includes forming a metal layer covering the recess and the obverse surface and grinding the metal layer by chemical mechanical polishing until an entirety of the obverse surface is exposed.
